(19) United States
(12) Patent Application Publication
(10) Pub. No.: US 2014/0209872 A1
(43) Pub. Date: Jul. 31, 2014

(54) COMPOUND, ORGANIC LIGHT EMITTING DEVICE INCLUDING THE COMPOUND, AND FLAT DISPLAY DEVICE INCLUDING THE ORGANIC LIGHT EMITTING DEVICE

(71) Applicant: Samsung Display Co.,Ltd., Yongin-City (KR)

(72) Inventors: Jun-Ha Park, Yongin-City (KR); Seok-Hwan Hwang, Yongin-City (KR); Young-Kook Kim, Yongin-City (KR); Hye-Jin Jung, Yongin-City (KR); Eun-Young Lee, Yongin-City (KR); Jin-O Lim, Yongin-City (KR); Sang-Hyun Han, Yongin-City (KR); Eun-Jae Jeong, Yongin-City (KR); Soo-Yon Kim, Yongin-City (KR); Jong-Hyuk Lee, Yongin-City (KR)

(21) Appl. No.: 13/952,405

(22) Filed: Jul. 26, 2013

(30) Foreign Application Priority Data
Jan. 28, 2013 (KR) 10-2013-0009504

(51) Int. Cl. H01L 51/00

(52) U.S. Cl. CPC H01L 51/006; H01L 51/0061
USPC 257/40; 558/422; 546/171; 546/285; 546/264; 544/353; 546/257; 549/460; 544/212

(57) ABSTRACT

A compound having an electron injection capability and/or electron transport capability represented by Formula 1, an organic light emitting device including the compound; and a flat display device including the organic light emitting device.

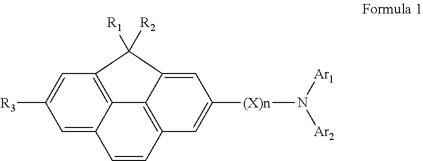

The descriptions of substituents are referred to in the detailed description.

### CLAIM OF PRIORITY

This application makes reference to, incorporates the same herein, and claims all benefits accruing under 35 U.S.C. §119 from an application for COMPOUND, ORGANIC LIGHT EMITTING DEVICE INCLUDING THE COMPOUND, AND FLAT DISPLAY DEVICE INCLUDING THE ORGANIC LIGHT EMITTING DEVICE, earlier filed in the Korean Intellectual Property Office on Jan. 28, 2013 and there duly assigned Serial No. 10-2013-0009504.

### BACKGROUND OF THE INVENTION

1. Field of the Invention

The present invention relates to a compound, an organic light emitting device including the compound, and a flat display device including the organic light emitting device.

2. Description of the Related Art

Organic light-emitting devices (OLEDs), which are self-emitting devices, have advantages such as wide viewing angles, excellent contrast, quick response, high brightness, and excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. The HTL, the EML, and the ETL are organic thin films formed of organic compounds.

An operating principle of an OLED having the above-described structure is as follows.

When a voltage is applied between the anode and the cathode, holes injected from the anode move to the EML via the HTL, and electrons injected from the cathode move to the EML via the ETL. The holes and electrons (carriers) recombine in the organic EML to generate excitons. When the excitons drop from an excited state to a ground state, light is emitted.

There is a continuous demand for a material having excellent electrical stability, high electron transporting ability or light emitting property, and high glass transition temperature, and that is capable of preventing crystallization.

### SUMMARY OF THE INVENTION

The present invention provides a compound having high electron transport capabilities or light emitting capabilities, having high glass transition temperatures, and capable of preventing a crystallization, that are useful for hole transport materials or hole injection materials suitable for fluorescence and phosphorescence of all colors such as red, green, blue, and white.

The present invention also provides an organic light emitting device including the compound and having high efficiency, low voltage, high brightness, and a long lifespan.

The present invention also provides a flat display device including the organic light emitting device.

According to an aspect of the present invention, there is provided is a compound represented by Formula 1 below:

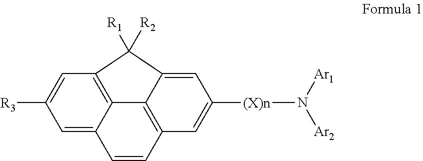

Wherein in Formula 1, R₁ and R₂ may be each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group; R₃ may be hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group, X may be a connector that is a substituted or unsubstituted C₆-C₁₀ arylene group except an anthracene, a substituted or unsubstituted C₂-C₁₁ heteroarylene group, or a substituted or unsubstituted C₆-C₆₀ condensed polycyclic group; Ar₁ and Ar₂ may be each independently a substituted or unsubstituted C₂-C₆₀ heteroaryl group; a C₆-C₆₀ aryl group substituted with an electron withdrawing group; a C₆-C₆₀ condensed polycyclic group substituted with an electron withdrawing group, and n is an integer of 1 to 10.

According to another aspect of the present invention, there is provided an organic light-emitting device including a first electrode; a second electrode disposed opposite to the first electrode; and an organic layer disposed between the first electrode and the second electrode and including an emission layer, wherein the organic layer includes at least one of the above-described compounds of Formula 1.

According to another aspect of the present invention, there is provided a flat display device including the organic light-emitting device (OLED), wherein a first electrode of the OLED is electrically connected to a source electrode of a thin film transistor or a drain electrode.

Because a compound represented by Formula 1 has excellent electron transport ability, the compound is useful as an electron transport material or an electron injection material suitable for a fluorescent device and a phosphorescent device of red, green, blue, and white colors. By using the compound, an OLED having high efficiency, low voltage, high brightness, and a long lifespan may be manufactured.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 schematically illustrates an organic light emitting device according to an embodiment of the present invention.

### DETAILED DESCRIPTION OF THE INVENTION

According to an aspect of the present invention, there is provided a compound represented by Formula 1 below:

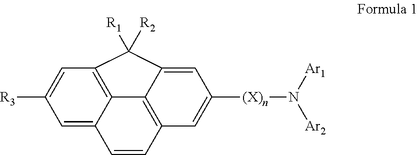

In Formula 1 above, R₁ and R₂ may be each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group; R₃ may be hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group; X may be a connector that is a substituted or unsubstituted C₆-C₁₀ arylene group except anthracene, a substituted or unsubstituted C₂-C₁₁ heteroarylene group, or a substituted or unsubstituted C₆-C₆₀ condensed polycyclic group; Ar₁ and Ar₂ may be each independently a substituted or unsubstituted C₂-C₆₀ heteroaryl group; a C₆-C₆₀ aryl group substituted with an electron withdrawing group; or a C₆-C₆₀ condensed polycyclic group substituted with an electron withdrawing group, and n may be an integer of 1 to 10.

According to another aspect of the present invention, the compounds of Formula 1 may have functions as an electron injecting material or an electron transport material for the organic light emitting device (OLED). Also, the compounds of Formula 1 may have a high glass transition temperature (Tg) or a high melting point due to a fused chain. Accordingly, thermal resistance increases with respect to Joule's heat arising between organic layers or between the organic layer and a metal electrode during an electroluminescence, and tolerance increases under a high temperature environment. An organic electroluminescence device manufactured by using the compounds according to the present invention has a high durability during maintenance and an operation.

An aryl-shaped or a heteroaryl-shaped linker X exists between a cyclopentaphenanthrene moiety and an arylamine moiety in the compound of Formula 1 of the present invention. Accordingly, a dipole moment of the compound of Formula 1 improves and an electron injecting ability or an electron transport ability of the compound becomes excellent.

A substituent of a compound of Formula 1 will be described in greater detail.

According to an embodiment of the present invention, the term “electron withdrawing group” used herein refers to a substituent including at least one element having a large electronegativity, for example, the term refers to substituents including elements having a large electronegativity such as fluorine (F), oxygen (O), nitrogen (N), chlorine (N), or the like, but is not limited thereto.

As the electron withdrawing group is substituted at Ar₁ and Ar₂, the compound of Formula 1, according to an embodiment of the present invention, may have the electron injecting ability and/or the electron transport ability.

According to another embodiment of the present invention, the electron withdrawing group may be —F, —Cl, —Br, —I, —CN, a hydroxyl group, —NO₂, an amino group, an amidino group, hydrazine, hydrazone, a carboxyl group or a salt thereof, a sulfonic acid or a salt thereof, a phosphoric acid or a salt thereof, a C₂-C₆₀ heteroaryl group, a C₁-C₆₀ alkyl group substituted with at least one —F, a C₁-C₆₀ alkoxy group substituted with at least one —F, a C₂-C₆₀ alkenyl group substituted with at least one —F, or a C₂-C₆₀ alkynyl group substituted with at least one —F, but is not limited thereto.

According to another embodiment of the present invention, R₁ and R₂ in Formula 1 above may be each independently a C₁-C₃₀ alkyl group.

According to another embodiment of the present invention, R₃ of Formula 1 may be at least one of hydrogen, deuterium, or any one of Formulae 2a to 2d.

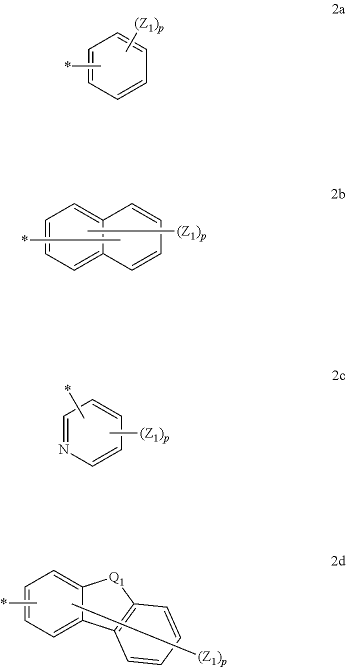

In Formulae 2a to 2d, Q₁ may be a connector represented by —S— or —O—; Z₁ may be hydrogen, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, a C₆-C₂₀ aryl group; or an amino group substituted with a C₆-C₂₀ aryl group or a C₂-C₂₀ heteroaryl group, a halogen group, a cyano group, a nitro group, a hydroxyl group, or a carboxy group; p is an integer of 1 to 7; and * represents a bonding.

According to another embodiment of the present invention, in Formula 1, X may be any connector of Formulae 3a to 3d.

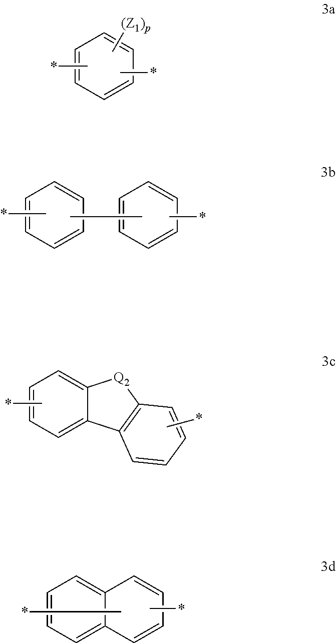

In Formulae 3a to 3d, Q₂ may be a connector represented by —C(R₃₀)(R₃₁)—, —S— or —O—; Z₁, R₃₀ and R₃₁ may be each independently hydrogen, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, a halogen group, a cyano group, a nitro group, a hydroxyl group, or a carboxy group; p is an integer of 1 to 4; and * represents a bonding.

According to another embodiment of the present invention, in Formula 1, Ar₁ and Ar₂ may be any one of Formulae 4a to 4e.

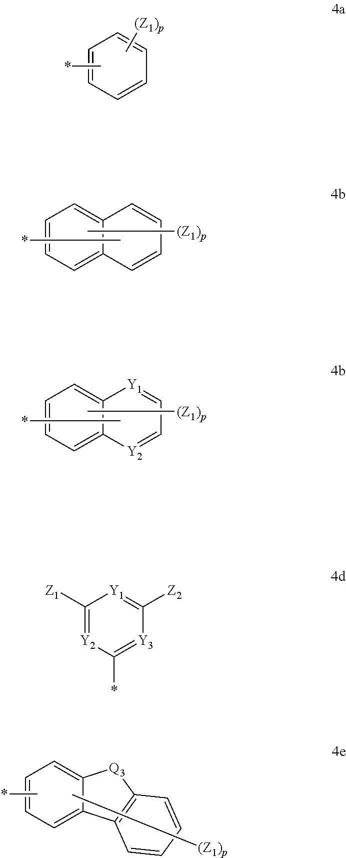

In Formulae 4a to 4e, Q₃ may be a connector represented by —C(R₃₀)(R₃₁)—; Z₁, Z₂, R₃₀ and R₃₁ may be each independently hydrogen, deuterium, —F, —Cl, —Br, —I, —CN, a hydroxyl group, —NO₂, an amino group, an amidino group, hydrazine, hydrazone, a carboxyl group or a salt thereof, a sulfonic acid or a salt thereof, a phosphoric acid or a salt thereof, a C₂-C₆₀ heteroaryl group, a C₁-C₆₀ alkyl group substituted with at least one —F, a C₁-C₆₀ alkoxy group substituted with at least one —F, a C₂-C₆₀ alkenyl group substituted with at least one —F, or a C₂-C₆₀ alkynyl group substituted with at least one —F, or a C₆-C₆₀ aryl group; Y₁, Y₂ and Y₃ may be each independently —N═ or —CH═; p is an integer of 1 to 4; and * represents a bonding.

Hereinafter, a definition of representative substituents among all of the substituents used in the present invention is as follows (carbon numbers limiting the substituents are non-limiting and do not limit characteristics of the substituents).

Examples of the unsubstituted C₁-C₆₀ alkyl group used herein are linear or branched C₁-C₆₀ alkyl groups, such as a methyl group, an ethyl group, a propyl group, an isobutyl group, a sec-butyl group, a pentyl group, an iso-amyl group, a hexyl group, or the like. In the substituted C₁-C₆₀ alkyl group, at least one hydrogen of the unsubstituted C₁-C₆₀ alkyl group described above is substituted with deuterium, a halogen atom, a hydroxyl group, a nitro group, a cyano group, an amino group, an amidino group, hydrazine, hydrazone, a carboxyl group or salts thereof, a sulfonic acid group or salts thereof, a phosphoric acid group or salts thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group.

As used herein, the unsubstituted C₂-C₆₀ alkenyl group is a hydrocarbon chain having a carbon-carbon double bond in the center or at a terminal of the unsubstituted C₂-C₆₀ alkyl group. Examples of the alkenyl group are an ethenyl group, a propenyl group, a butenyl group, and the like. At least one hydrogen in the unsubstituted C₂-C₆₀ alkenyl group may be substituted with those substituents described above in conjunction with the substituted C₁-C₆₀ alkyl group.

The unsubstituted C₂-C₆₀ alkynyl group is a C₂-C₆₀ alkyl group having at least one carbon-carbon triple bond in the center or at a terminal thereof. Examples of the unsubstituted C₂-C₆₀ alkynyl group are an acetylene group, a propylene group, a phenylacetylene group, a naphthyl acetylene group, an isopropyl acetylene group, a t-butyl acetylene group, a diphenyl acetylene group, and the like. At least one hydrogen in the unsubstituted C₂-C₆₀ alkynyl group may be substituted with those substituents described above in conjunction with the substituted C₁-C₆₀ alkyl group.

The unsubstituted C₃-C₆₀ cycloalkyl group is a C₃-C₆₀ ring-shaped alkyl group. At least one hydrogen in the unsubstituted C₃-C₆₀ cycloalkyl group may be substituted with those substituents described above in conjunction with the substituted C₁-C₆₀ alkyl group.

The unsubstituted C₁-C₆₀ alkoxy group may be a group represented by —OA, wherein A is an unsubstituted C₁-C₆₀ alkyl group described above. Non-limiting examples of the unsubstituted C₁-C₆₀ alkoxy group are a methoxy group, an ethoxy group, an isopropyloxy group, a butoxy group, and a pentoxy group. At least one of the hydrogens in the unsubstituted C₁-C₆₀ alkoxy group may be substituted with those substituents described above in conjunction with the substituted C₁-C₆₀ alkyl group.

The unsubstituted C₆-C₆₀ aryl group is a monovalent group having a carbocyclic aromatic system including at least one aromatic ring. The term “aryl” as used herein includes an aromatic system such as phenyl, naphthyl or anthracenyl. When the aryl group and the arylene group have at least two rings, they may be fused to each other via a single bond. At least one hydrogen in the unsubstituted C₆-C₆₀ aryl group and the arylene group may be substituted with those substituents described above in conjunction with the C₁-C₆₀ alkyl group.

Examples of the substituted or unsubstituted C₆-C₆₀ aryl group are a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m- or p-fluorophenyl group and a dichlorophenyl group), a dicyanophenyl group, a trifluoromethoxyphenyl group, an o-, m- or p-tolyl group, an o-, m- or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

The unsubstituted C₂-C₆₀ heteroaryl group includes one, two, three or four heteroatoms selected from N, O, P, or S, and when the unsubstituted C₂-C₆₀ heteroaryl group has at least two rings, they may be fused to each other via a single bond. Examples of the unsubstituted C₂-C₆₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolyl group, an isoquinolyl group, a dibenzothiophene group, or the like. Also, at least one hydrogen in the unsubstituted C₂-C₆₀ heteroaryl group and the heteroarylene group may be substituted with those substituents described with reference to the C₁-C₆₀ alkyl group.

The unsubstituted C₆-C₆₀ aryloxy group indicates —OA₁ (where A₁ is a substituted or unsubstituted C₆-C₆₀ aryl group described above). Examples of the aryloxy group include a phenoxy group or the like. At least one hydrogen in the unsubstituted C₆-C₆₀ aryloxy group and the heteroarylene group may be substituted with those substituents described with reference to the C₁-C₆₀ alkyl group.

The unsubstituted C₆-C₆₀ arylthio group indicates —SA₃ (where A₃ is a substituted or unsubstituted C₆-C₆₀ aryl group described above). Examples of the unsubstituted arylthio group include a benzenthio group, a naphthylthio group, or the like. At least one hydrogen in the unsubstituted C₆-C₆₀ arylthio group and the heteroarylene group may be substituted with those substituents described with reference to the C₁-C₆₀ alkyl group.

The term “the substituted C₆-C₆₀ condensed polycyclic group” used herein refers to a substituent including two or more rings, wherein at least one aromatic ring and at least one non-aromatic ring are fused, or a substituent having an unsaturated group but that is incapable of having a conjugated structure. The condensed polycyclic group is distinguished from the aryl group or the heteroaryl group in that the condensed polycyclic group does not have aromaticity.

Examples of the compounds represented by Formula 1 are as follows, but are not limited thereto:

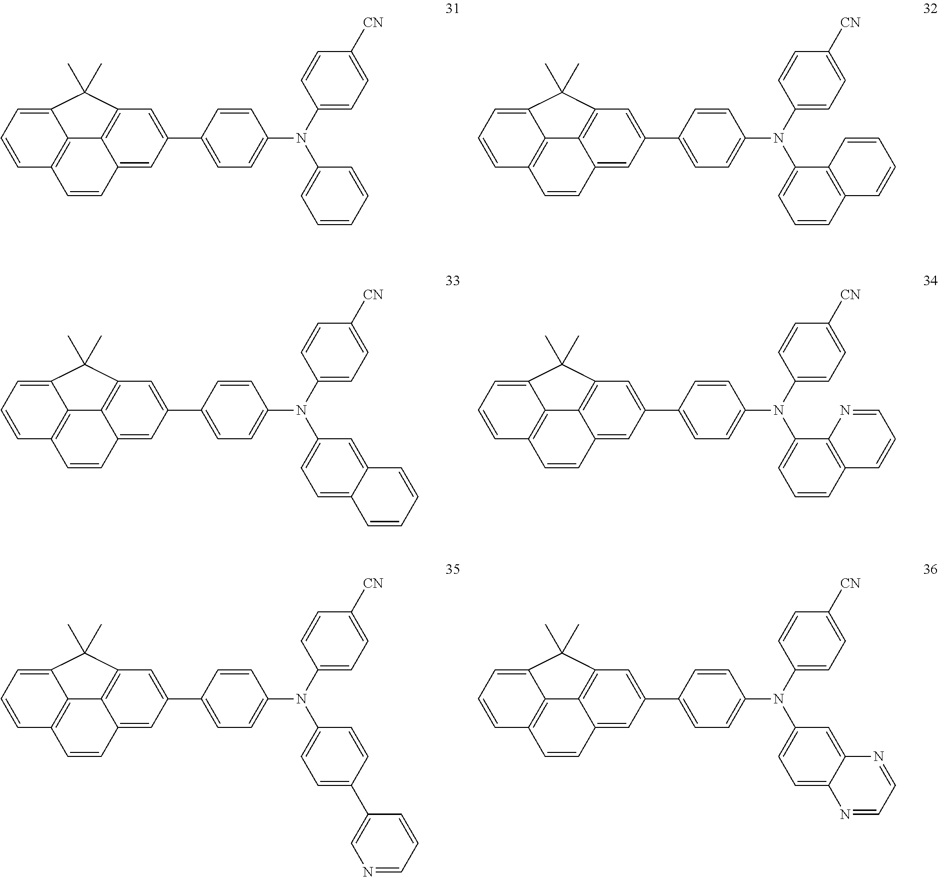 [SMILES: CC1(C)c2cccc3ccc4cc(-c5ccc(N(c6ccccc6)c6ccc(C#N)cc6)cc5)cc1c4c23 ; CC1(C)c2cccc3ccc4cc(-c5ccc(N(c6ccc(C#N)cc6)c6cccc7ccccc67)cc5)cc1c4c23 ; CC1(C)c2cccc3ccc4cc(-c5ccc(N(c6ccc(C#N)cc6)c6ccc7ccccc7c6)cc5)cc1c4c23 ; CC1(C)c2cccc3ccc4cc(-c5ccc(N(c6ccc(C#N)cc6)c6cccc7cccnc67)cc5)cc1c4c23 ; CC1(C)c2cccc3ccc4cc(-c5ccc(N(c6ccc(C#N)cc6)c6ccc(-c7cccnc7)cc6)cc5)cc1c4c23 ; CC1(C)c2cccc3ccc4cc(-c5ccc(N(c6ccc(C#N)cc6)c6ccc7nccnc7c6)cc5)cc1c4c23]

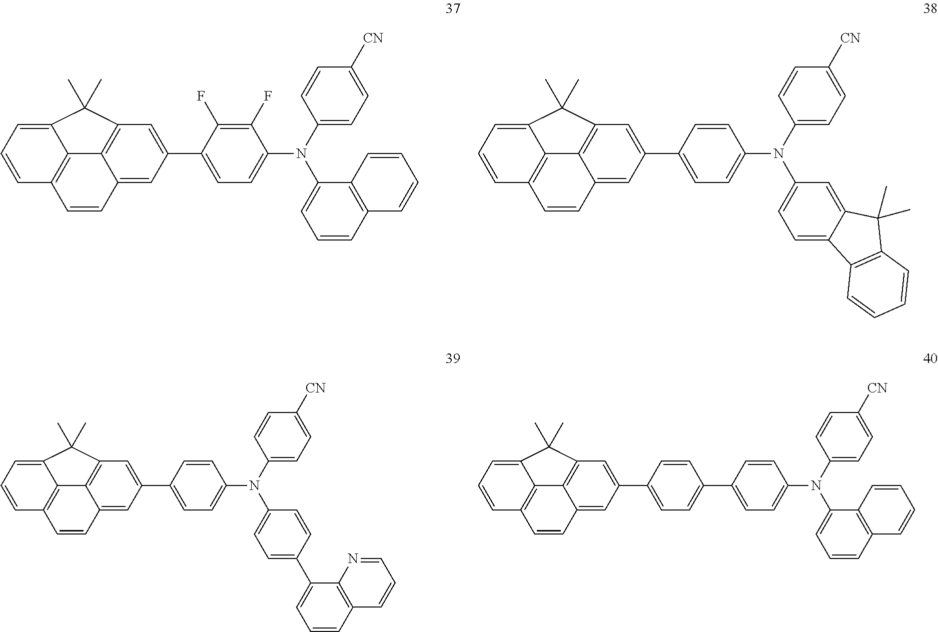 [SMILES: CC1(C)c2cccc3ccc4cc(-c5ccc(N(c6ccc(C#N)cc6)c6cccc7ccccc67)c(F)c5F)cc1c4c23 ; CC1(C)c2ccccc2-c2ccc(N(c3ccc(C#N)cc3)c3ccc(-c4cc5c6c(ccc7cccc(c76)C5(C)C)c4)cc3)cc21 ; CC1(C)c2cccc3ccc4cc(-c5ccc(N(c6ccc(C#N)cc6)c6ccc(-c7cccc8cccnc78)cc6)cc5)cc1c4c23 ; CC1(C)c2cccc3ccc4cc(-c5ccc(-c6ccc(N(c7ccc(C#N)cc7)c7cccc8ccccc78)cc6)cc5)cc1c4c23]

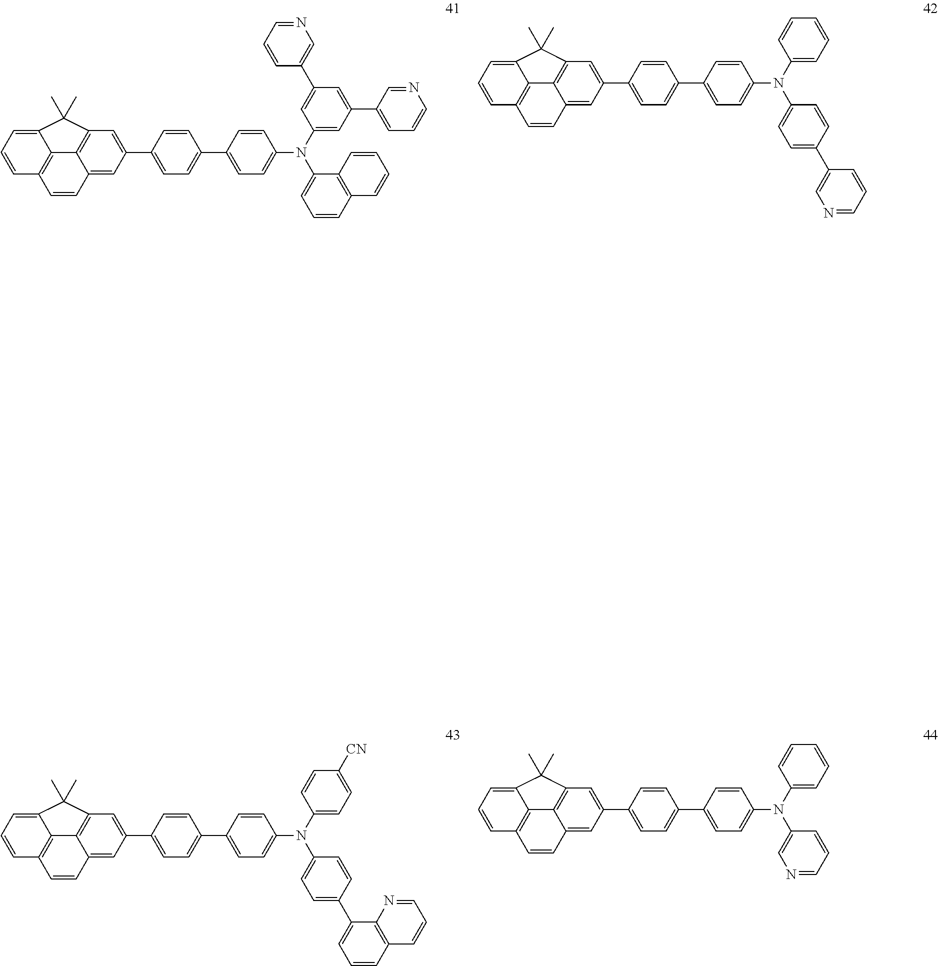 [SMILES: CC1(C)c2cccc3ccc4cc(-c5ccc(-c6ccc(N(c7cc(-c8cccnc8)cc(-c8cccnc8)c7)c7cccc8ccccc78)cc6)cc5)cc1c4c23 ; CC1(C)c2cccc3ccc4cc(-c5ccc(-c6ccc(N(c7ccccc7)c7ccc(-c8cccnc8)cc7)cc6)cc5)cc1c4c23 ; CC1(C)c2cccc3ccc4cc(-c5ccc(-c6ccc(N(c7ccc(C#N)cc7)c7ccc(-c8cccc9cccnc89)cc7)cc6)cc5)cc1c4c23 ; CC1(C)c2cccc3ccc4cc(-c5ccc(-c6ccc(N(c7ccccc7)c7cccnc7)cc6)cc5)cc1c4c23]

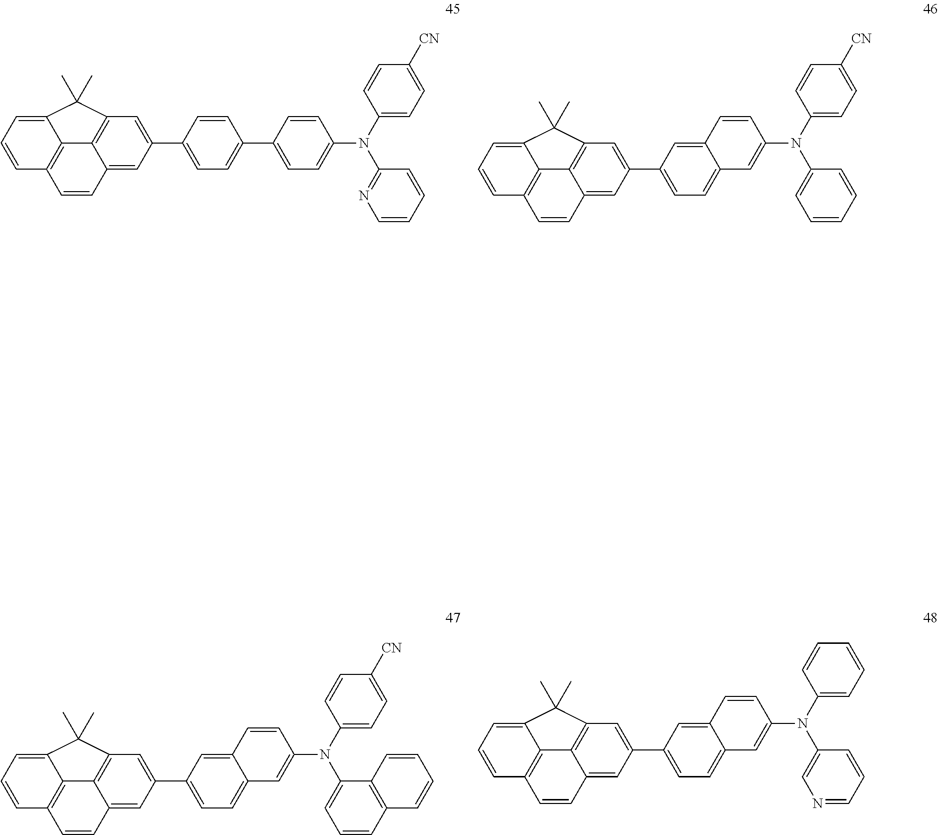 [SMILES: CC1(C)c2cccc3ccc4cc(-c5ccc(-c6ccc(N(c7ccc(C#N)cc7)c7ccccn7)cc6)cc5)cc1c4c23 ; CC1(C)c2cccc3ccc4cc(-c5ccc6cc(N(c7ccccc7)c7ccc(C#N)cc7)ccc6c5)cc1c4c23 ; CC1(C)c2cccc3ccc4cc(-c5ccc6cc(N(c7ccc(C#N)cc7)c7cccc8ccccc78)ccc6c5)cc1c4c23 ; CC1(C)c2cccc3ccc4cc(-c5ccc6cc(N(c7ccccc7)c7cccnc7)ccc6c5)cc1c4c23]

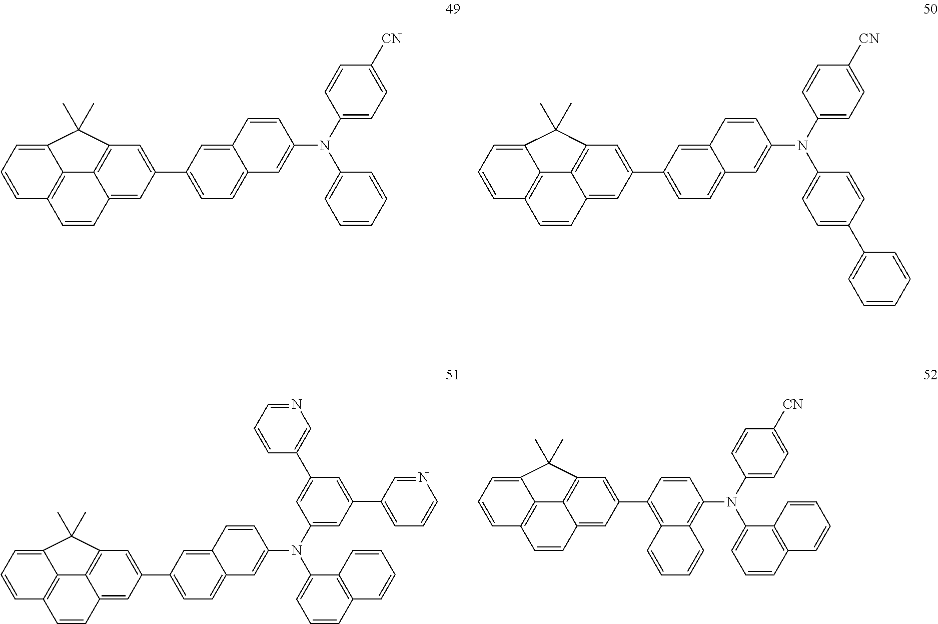 [SMILES: CC1(C)c2cccc3ccc4cc(-c5ccc6cc(N(c7ccccc7)c7ccc(C#N)cc7)ccc6c5)cc1c4c23 ; CC1(C)c2cccc3ccc4cc(-c5ccc6cc(N(c7ccc(C#N)cc7)c7ccc(-c8ccccc8)cc7)ccc6c5)cc1c4c23 ; CC1(C)c2cccc3ccc4cc(-c5ccc6cc(N(c7cc(-c8cccnc8)cc(-c8cccnc8)c7)c7cccc8ccccc78)ccc6c5)cc1c4c23 ; CC1(C)c2cccc3ccc4cc(-c5ccc(N(c6ccc(C#N)cc6)c6cccc7ccccc67)c6ccccc56)cc1c4c23]

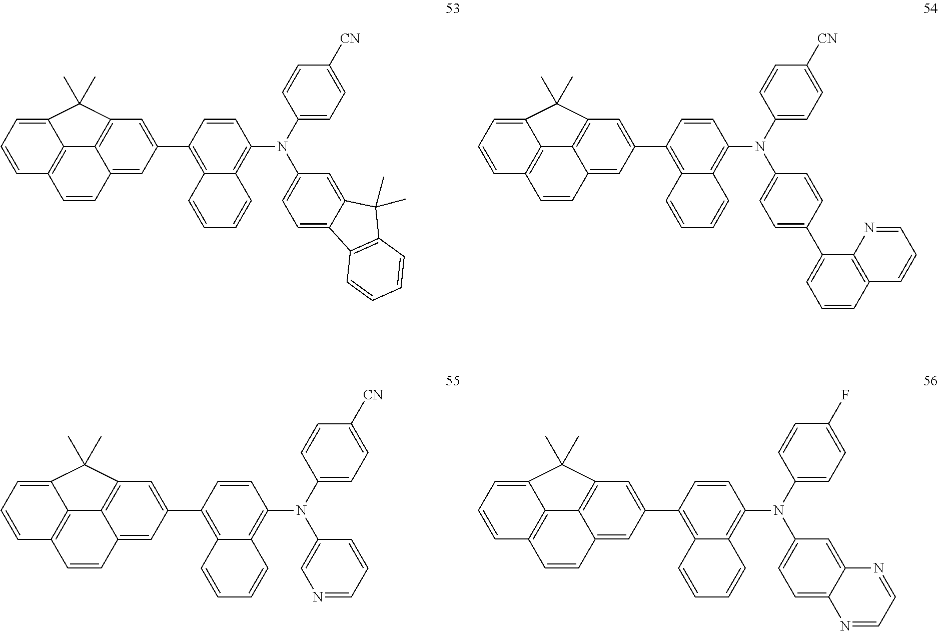 [SMILES: CC1(C)c2ccccc2-c2ccc(N(c3ccc(C#N)cc3)c3ccc(-c4cc5c6c(ccc7cccc(c76)C5(C)C)c4)c4ccccc34)cc21 ; CC1(C)c2cccc3ccc4cc(-c5ccc(N(c6ccc(C#N)cc6)c6ccc(-c7cccc8cccnc78)cc6)c6ccccc56)cc1c4c23 ; CC1(C)c2cccc3ccc4cc(-c5ccc(N(c6ccc(C#N)cc6)c6cccnc6)c6ccccc56)cc1c4c23 ; CC1(C)c2cccc3ccc4cc(-c5ccc(N(c6ccc(F)cc6)c6ccc7nccnc7c6)c6ccccc56)cc1c4c23]

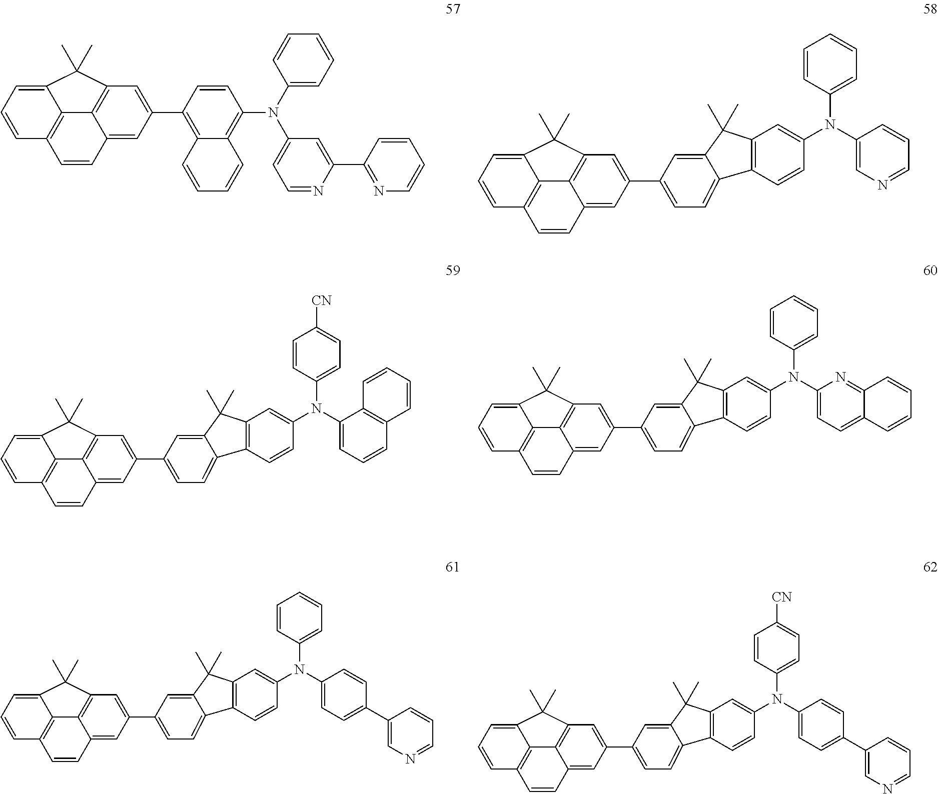

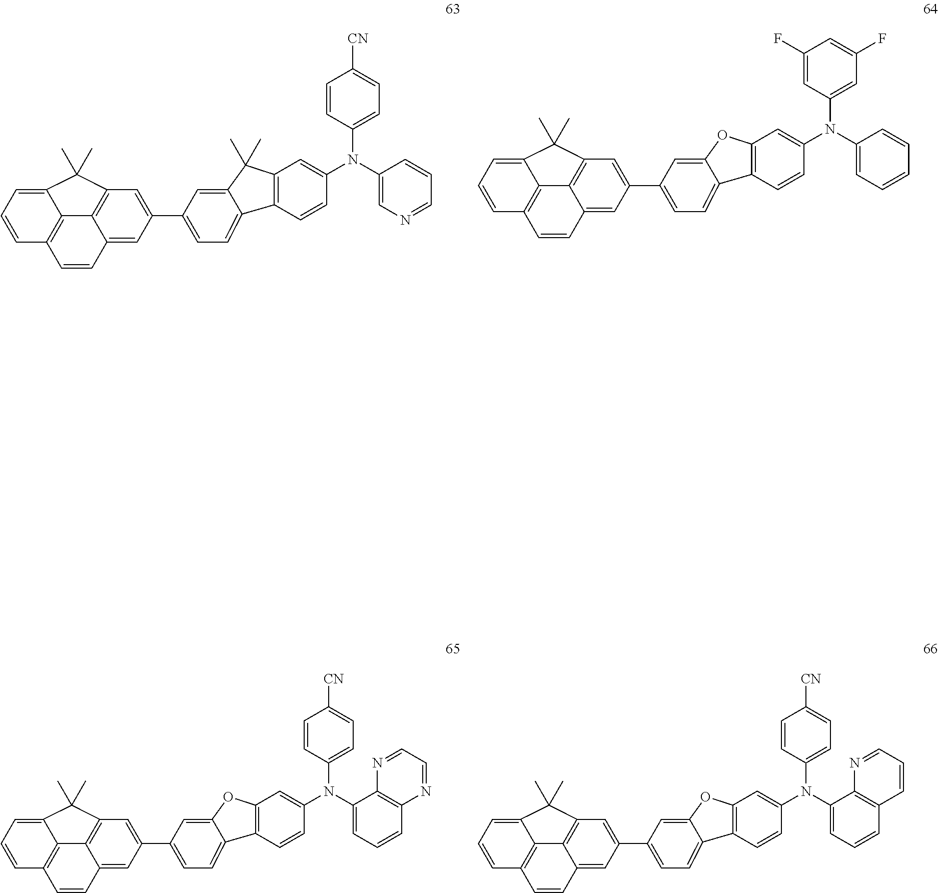 [SMILES: CC1(C)c2cc(-c3cc4c5c(ccc6cccc(c65)C4(C)C)c3)ccc2-c2ccc(N(c3ccc(C#N)cc3)c3cccnc3)cc21 ; CC1(C)c2cccc3ccc4cc(-c5ccc6c(c5)oc5cc(N(c7ccccc7)c7cc(F)cc(F)c7)ccc56)cc1c4c23 ; CC1(C)c2cccc3ccc4cc(-c5ccc6c(c5)oc5cc(N(c7ccc(C#N)cc7)c7cccc8nccnc78)ccc56)cc1c4c23 ; CC1(C)c2cccc3ccc4cc(-c5ccc6c(c5)oc5cc(N(c7ccc(C#N)cc7)c7cccc8cccnc78)ccc56)cc1c4c23]

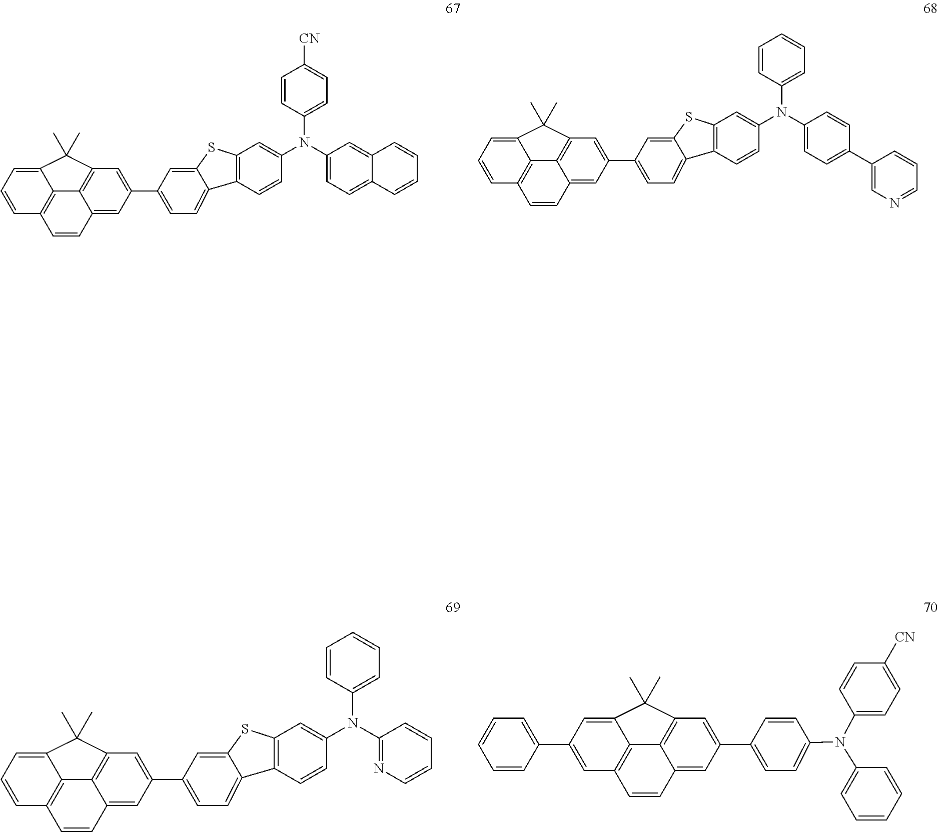 [SMILES: CC1(C)c2cccc3ccc4cc(-c5ccc6c(c5)sc5cc(N(c7ccc(C#N)cc7)c7ccc8ccccc8c7)ccc56)cc1c4c23 ; CC1(C)c2cccc3ccc4cc(-c5ccc6c(c5)sc5cc(N(c7ccccc7)c7ccc(-c8cccnc8)cc7)ccc56)cc1c4c23 ; CC1(C)c2cccc3ccc4cc(-c5ccc6c(c5)sc5cc(N(c7ccccc7)c7ccccn7)ccc56)cc1c4c23 ; CC1(C)c2cc(-c3ccccc3)cc3ccc4cc(-c5ccc(N(c6ccccc6)c6ccc(C#N)cc6)cc5)cc1c4c23]

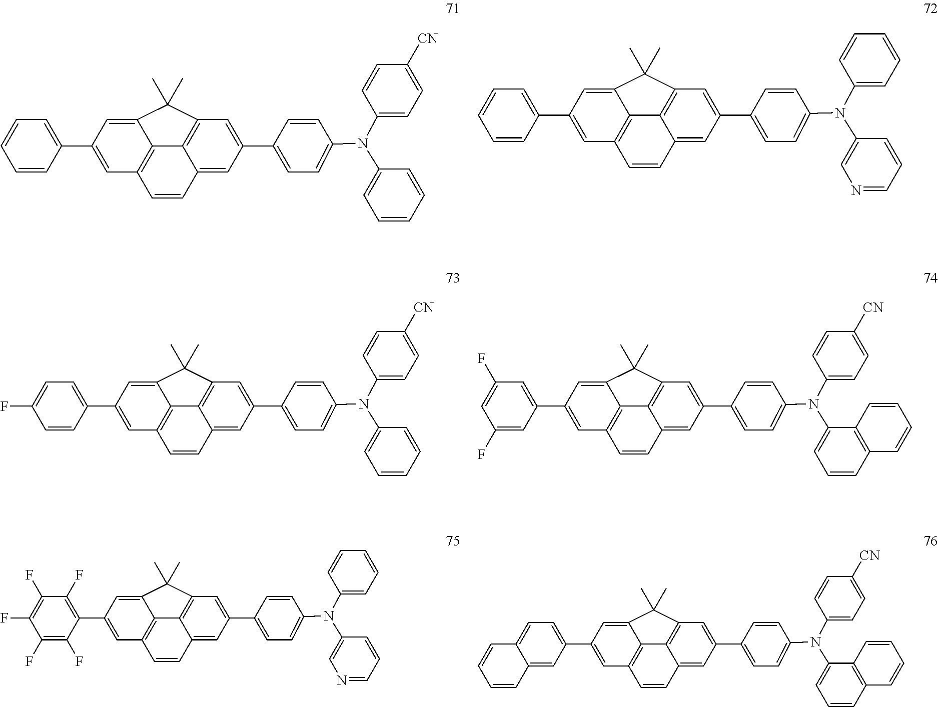 [SMILES: CC1(C)c2cc(-c3ccccc3)cc3ccc4cc(-c5ccc(N(c6ccccc6)c6ccc(C#N)cc6)cc5)cc1c4c23 ; CC1(C)c2cc(-c3ccccc3)cc3ccc4cc(-c5ccc(N(c6ccccc6)c6cccnc6)cc5)cc1c4c23 ; CC1(C)c2cc(-c3ccc(F)cc3)cc3ccc4cc(-c5ccc(N(c6ccccc6)c6ccc(C#N)cc6)cc5)cc1c4c23 ; CC1(C)c2cc(-c3ccc(N(c4ccc(C#N)cc4)c4cccc5ccccc45)cc3)cc3ccc4cc(-c5cc(F)cc(F)c5)cc1c4c23 ; CC1(C)c2cc(-c3ccc(N(c4ccccc4)c4cccnc4)cc3)cc3ccc4cc(-c5c(F)c(F)c(F)c(F)c5F)cc1c4c23 ; CC1(C)c2cc(-c3ccc(N(c4ccc(C#N)cc4)c4cccc5ccccc45)cc3)cc3ccc4cc(-c5ccc6ccccc6c5)cc1c4c23]

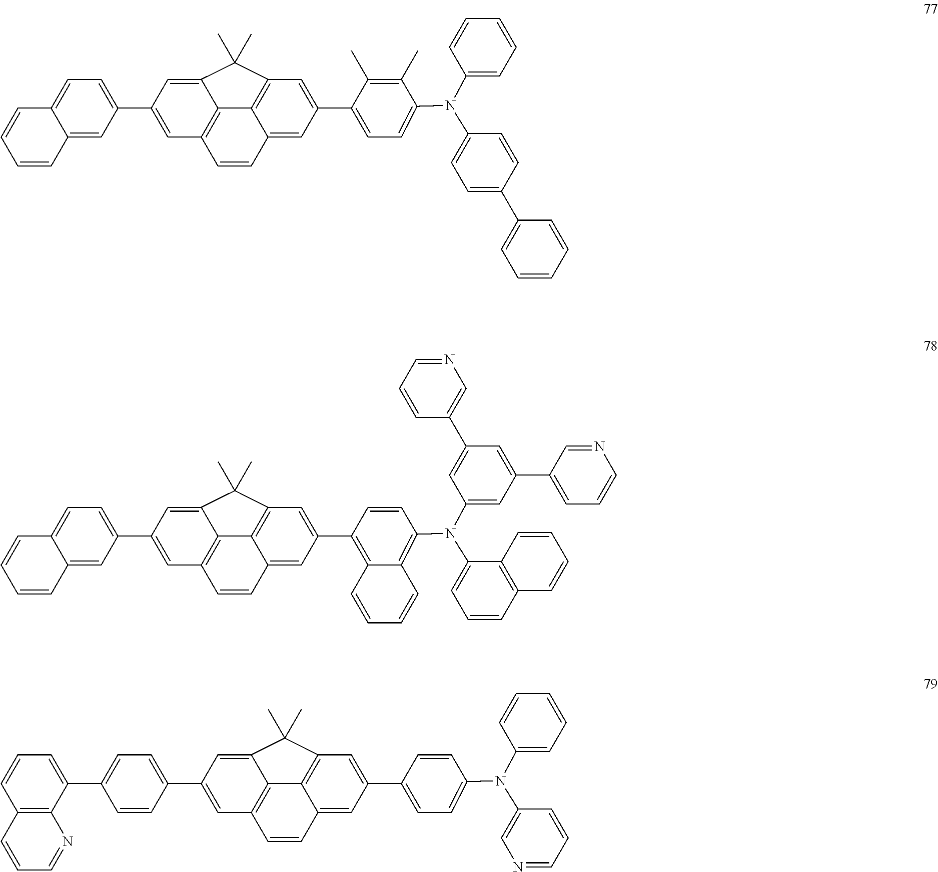 [SMILES: Cc1c(-c2cc3c4c(ccc5cc(-c6ccc7ccccc7c6)cc(c54)C3(C)C)c2)ccc(N(c2ccccc2)c2ccc(-c3ccccc3)cc2)c1C ; CC1(C)c2cc(-c3ccc4ccccc4c3)cc3ccc4cc(-c5ccc(N(c6cc(-c7cccnc7)cc(-c7cccnc7)c6)c6cccc7ccccc67)c6ccccc56)cc1c4c23 ; CC1(C)c2cc(-c3ccc(-c4cccc5cccnc45)cc3)cc3ccc4cc(-c5ccc(N(c6ccccc6)c6cccnc6)cc5)cc1c4c23]

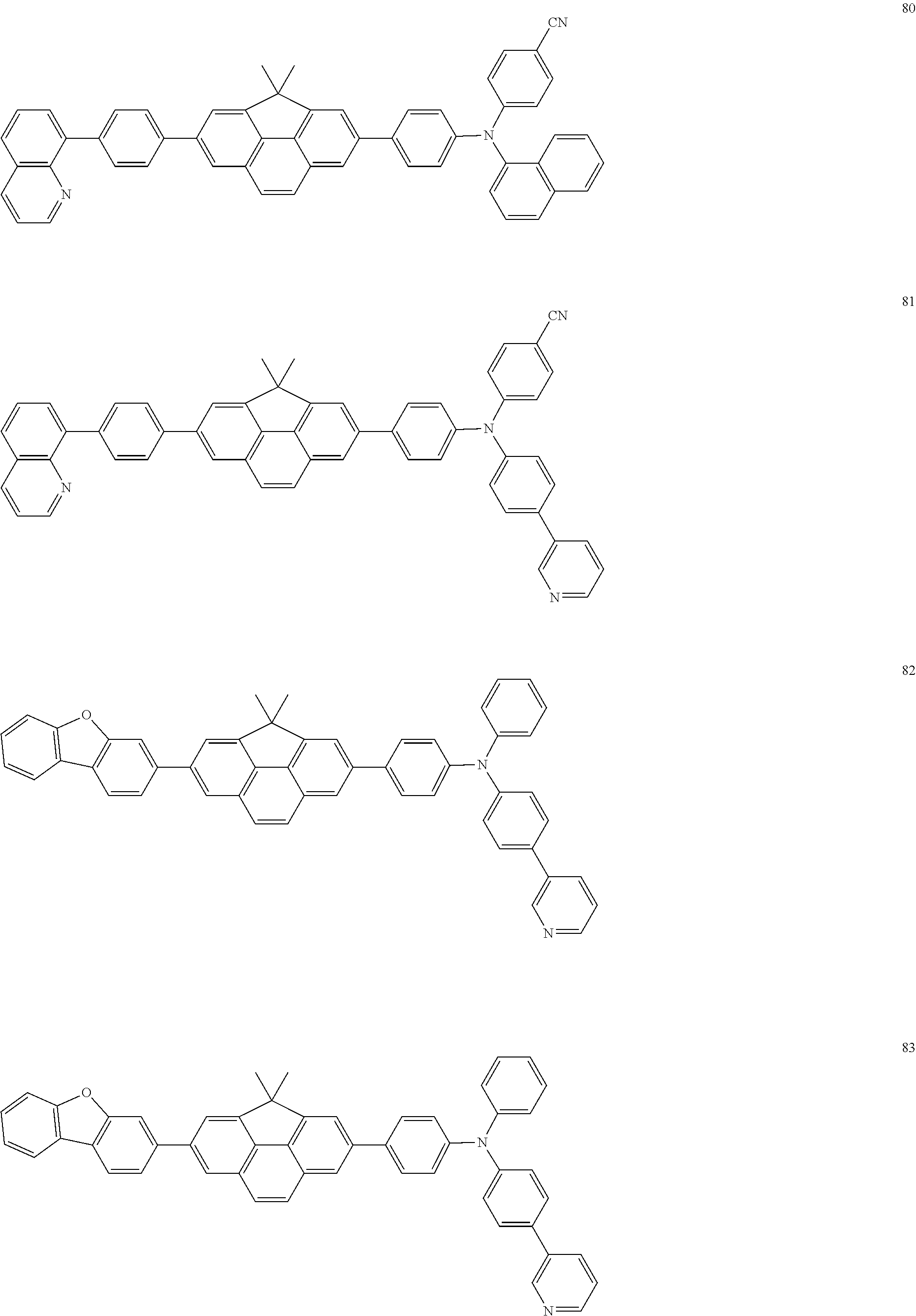 [SMILES: CC1(C)c2cc(-c3ccc(-c4cccc5cccnc45)cc3)cc3ccc4cc(-c5ccc(N(c6ccc(C#N)cc6)c6cccc7ccccc67)cc5)cc1c4c23 ; CC1(C)c2cc(-c3ccc(-c4cccc5cccnc45)cc3)cc3ccc4cc(-c5ccc(N(c6ccc(C#N)cc6)c6ccc(-c7cccnc7)cc6)cc5)cc1c4c23 ; CC1(C)c2cc(-c3ccc(N(c4ccccc4)c4ccc(-c5cccnc5)cc4)cc3)cc3ccc4cc(-c5ccc6c(c5)oc5ccccc56)cc1c4c23 ; CC1(C)c2cc(-c3ccc(N(c4ccccc4)c4ccc(-c5cccnc5)cc4)cc3)cc3ccc4cc(-c5ccc6c(c5)oc5ccccc56)cc1c4c23]

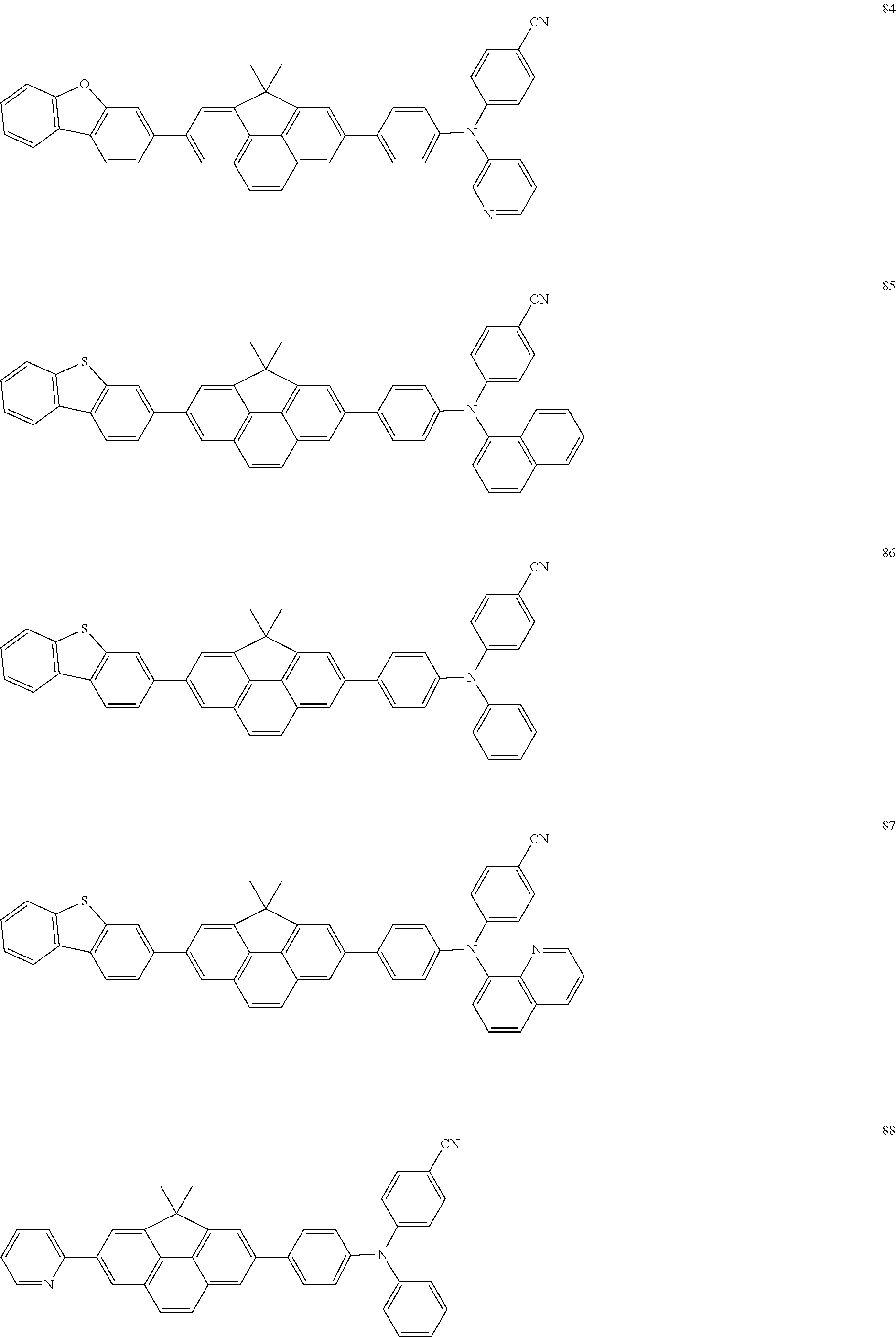 [SMILES: CC1(C)c2cc(-c3ccc(N(c4ccc(C#N)cc4)c4cccnc4)cc3)cc3ccc4cc(-c5ccc6c(c5)oc5ccccc56)cc1c4c23 ; CC1(C)c2cc(-c3ccc(N(c4ccc(C#N)cc4)c4cccc5ccccc45)cc3)cc3ccc4cc(-c5ccc6c(c5)sc5ccccc56)cc1c4c23 ; CC1(C)c2cc(-c3ccc(N(c4ccccc4)c4ccc(C#N)cc4)cc3)cc3ccc4cc(-c5ccc6c(c5)sc5ccccc56)cc1c4c23 ; CC1(C)c2cc(-c3ccc(N(c4ccc(C#N)cc4)c4cccc5cccnc45)cc3)cc3ccc4cc(-c5ccc6c(c5)sc5ccccc56)cc1c4c23 ; CC1(C)c2cc(-c3ccc(N(c4ccccc4)c4ccc(C#N)cc4)cc3)cc3ccc4cc(-c5ccccn5)cc1c4c23]

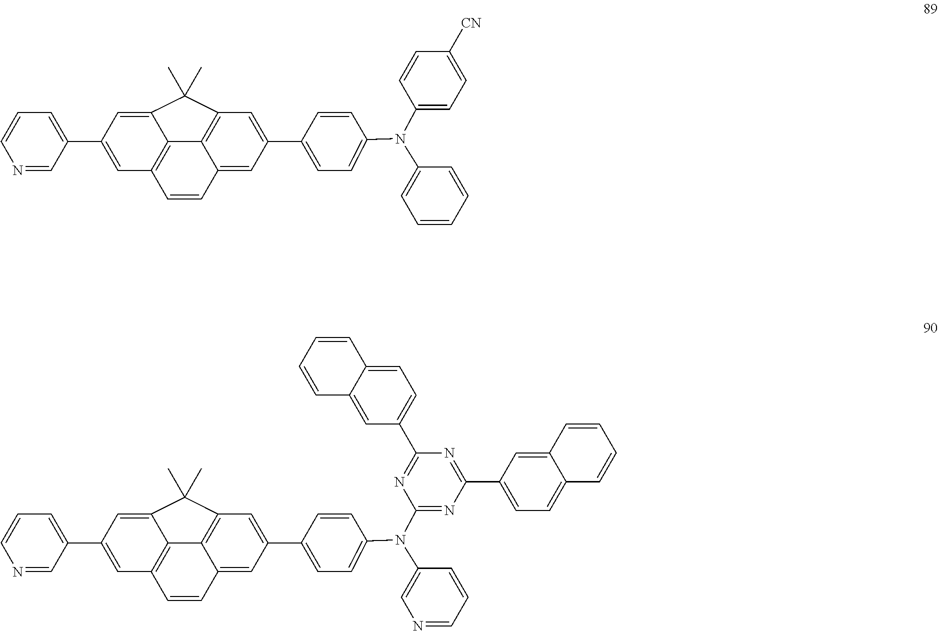 [SMILES: CC1(C)c2cc(-c3ccc(N(c4ccccc4)c4ccc(C#N)cc4)cc3)cc3ccc4cc(-c5cccnc5)cc1c4c23 ; CC1(C)c2cc(-c3ccc(N(c4cccnc4)c4nc(-c5ccc6ccccc6c5)nc(-c5ccc6ccccc6c5)n4)cc3)cc3ccc4cc(-c5cccnc5)cc1c4c23]

According to another aspect of the present invention, an organic light-emitting device may include a first electrode, a second electrode, and an organic layer disposed between the first electrode and the second electrode, wherein the organic layer includes at least one of the compounds of Formula 1 described above.

The organic layer may include at least one layer selected from among a hole injection layer (HIL), a hole transport layer (HTL), a functional layer having both hole injection and hole transport capabilities (hereinafter, “H-functional layer”), a buffer layer, an electron blocking layer (EBL), an emission layer (EML), a hole blocking layer (HBL), an electron transport layer (ETL), an electron injection layer (EIL), and a functional layer having both electron injection and electron transport capabilities (hereinafter, “E-functional layer”).

In greater detail, the organic layer may be used as an electron injection layer, an electron transport layer, or the E-functional layer.

According to another embodiment of the present invention, the organic light emitting device may include the emission layer, the electron injection layer, the electron transport layer, the hole injection layer, the hole transport layer, the H-functional layer, and the E-functional layer. The E-functional layer or the electron injection layer may include the compound of formula 1 according to an embodiment of the present invention, and the emission layer may include an anthracene-based compound, an arylamine-based compound, or a styryl-based compound.

According to another embodiment of the present invention, the organic light emitting device may include the electron injection layer, the electron transport layer, the emission layer, the hole injection layer, the hole transport layer, the H-functional layer or the E-functional layer. The electron injection layer, the electron transport layer, the H-functional layer according to an embodiment of the present invention may include the compound of formula 1; and at least one layer of a red layer, a green layer, a blue layer, or a white layer of the emission layer may include a phosphorescent compound.

According to another embodiment of the present invention, the electron injection layer, the electron transport layer, and the E-functional layer may further include a charge generating material in addition to the compound of formula 1. The charge-generating material may be, for example, a p-type dopant. The p-type dopant may be one of quinone derivatives, metal oxides, and compounds with a cyano group.

According to another embodiment of the present invention, the organic layer may include the electron transport layer, and the electron transport layer may further includes a metal complex. The metal complex may be a lithium (Li) complex.

According to another embodiment of the present invention, the organic layer may be formed by a wet process using the compound of formula 1.

According to another embodiment of the present invention, a flat display device may include the organic light emitting device, and the first electrode of the organic light emitting device may be electrically connected to a source electrode or a drain electrode of a thin film transistor.

In the present specification, the term “organic layer” as used herein refers to a single and/or multiple layers disposed between the first electrode and the second electrode of the organic light emitting device.

The organic layer may include an emission layer, and the compound of formula 1 may be included in the emission layer. In some embodiments, the organic layer may include at least one of the hole injection layer, the hole transport layer, and the H-functional layer, and at least one of the compounds of formula 1 above may be included in the hole injection layer, the hole transport layer, and the H-functional layer.

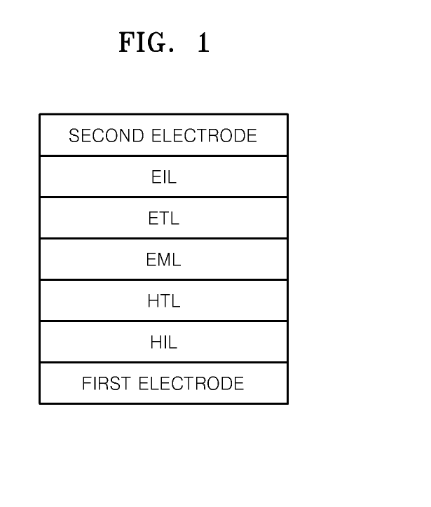

FIG. 1 schematically illustrates an organic light emitting device according to an embodiment of the present invention. Hereinafter, a structure and a method of manufacturing the organic light emitting device, according to an embodiment of the present invention, will be described in detail with reference to FIG. 1.

A substrate (not shown) may be any substrate that is used in existing organic light-emitting devices. In some embodiments, the substrate may be a glass substrate or a transparent plastic substrate with strong mechanical strength, thermal stability, transparency, surface smoothness, ease of handling, and water resistance.

The first electrode may be formed by depositing or sputtering a first electrode-forming material onto a surface of the substrate. When the first electrode is an anode, a material having a high work function may be used as the first electrode-forming material to facilitate hole injection. The first electrode may be a reflective electrode or a transmission electrode. Transparent and conductive materials such as ITO, IZO, SnO₂, and ZnO may be used to form the first electrode 13. The first electrode may be formed as a reflective electrode using magnesium (Mg), aluminum (Al group, aluminum-lithium (Al—Li), calcium (Ca), magnesium-indium (Mg—In), magnesium-silver (Mg—Ag), or the like.

The first electrode may have a single-layer structure or a multi-layer structure including at least two layers. For example, the first electrode may have a three-layered structure of ITO/Ag/ITO, but is not limited thereto.

The organic layer may be disposed on the first electrode.

The organic layer may include a hole injection layer (HIL), a hole transport layer (HTL), a H-functional layer, a buffer layer, an emission layer (EML), an electron transport layer (ETL), an electron injection layer (EIL), and E-functional layer.

The HIL may be formed on the first electrode by vacuum deposition, spin coating, casting, Langmuir-Blodgett (LB) deposition, or the like.

When the HIL is formed using vacuum deposition, vacuum deposition conditions may vary according to the compound that is used to form the HIL, and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed using spin coating, the coating conditions may vary according to the compound that is used to form the HIL, and the desired structure and thermal properties of the HIL to be formed. For example, the coating rate may be in the range of about 2000 rpm to about 5000 rpm, and a temperature at which heat treatment is performed to remove a solvent after coating may be in the range of about 80° C. to about 200° C. However, the coating conditions are not limited thereto.

The HIL may be formed of any material that is commonly used to form a HIL. Non-limiting examples of the material that is used to form the HIL may be N,N′-diphenyl-N,N′-bis-[4-(phenyl-m-tolyl-amino)-phenyl]-biphenyl-4,4′-diamine, (DNTPD), a phthalocyanine compound such as copper phthalocyanine, 4,4′,4″-tris(3-methylphenylphenylamino) triphenylamine (m-MTDATA), N,N′-di(1-naphthyl)-N,N′-diphenylbenzidine (NPB), TDATA, 2T-NATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS).

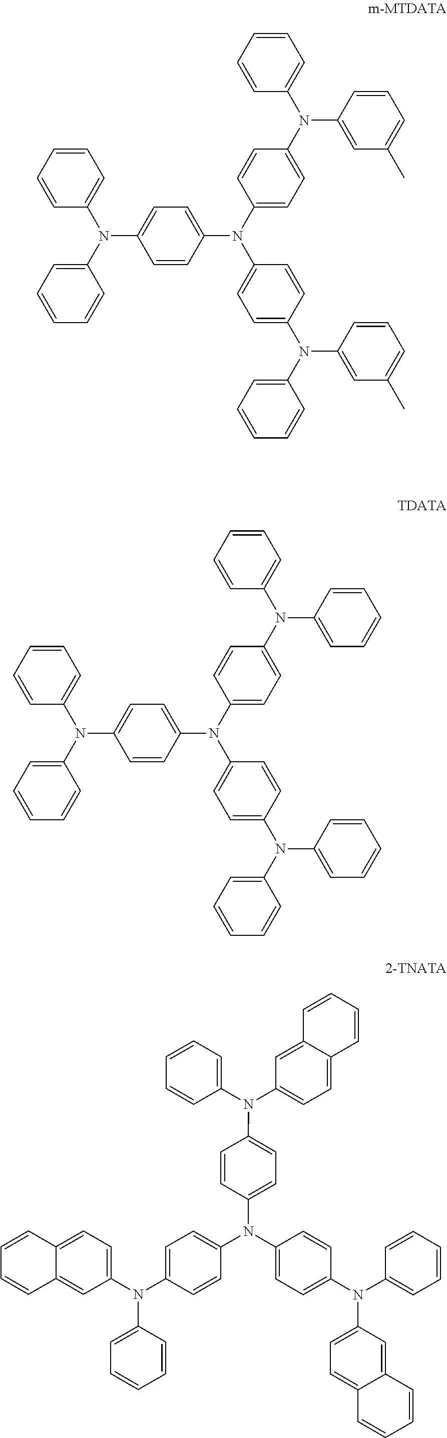 [SMILES: Cc1cccc(N(c2ccccc2)c2ccc(N(c3ccc(N(c4ccccc4)c4ccccc4)cc3)c3ccc(N(c4ccccc4)c4cccc(C)c4)cc3)cc2)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

The thickness of the HIL may be from about 100 Å to about 10000 Å, and in some embodiments, may be from about 100 Å to about 1000 Å. When the thickness of the HIL is within these ranges, the HIL may have good hole injecting ability without a substantial increase in driving voltage.

Then, an HTL may be formed on the HIL by using vacuum deposition, spin coating, casting, Langmuir-Blodgett (LB) deposition, or the like. When the HTL is formed using vacuum deposition or spin coating, the conditions for deposition and coating may be similar to those for the formation of the HIL, though the conditions for the deposition and coating may vary according to the material that is used to form the HTL.

Non-limiting examples of suitable known HTL forming materials may be carbazole derivatives, such as N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl grouptriphenylamine (TCTA), and N,N′-di(1-naphthyl group-N,N′-diphenylbenzidine) (NPB).

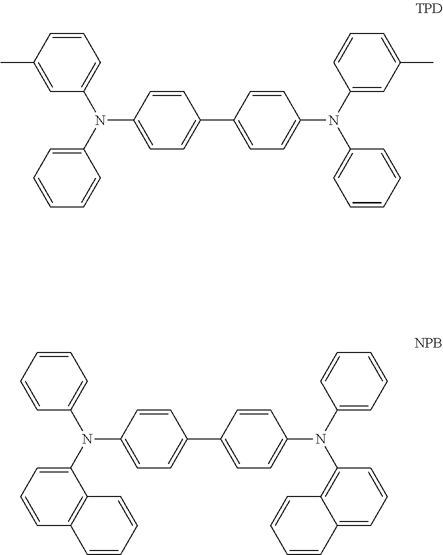

The thickness of the HTL may be from about 50 Å to about 2000 Å, and in some embodiments, may be from about 100 Å to about 1500 Å. When the thickness of the HTL is within these ranges, the HTL may have good hole transporting ability without a substantial increase in driving voltage.

The H-functional layer (having both hole injection and hole transport capabilities) may contain at least one material from each group of the hole injection layer materials and hole transport layer materials. The thickness of the H-functional layer may be from about 500 Å to about 10,000 Å, and in some embodiments, may be from about 100 Å to about 1,000 Å. When the thickness of the H-functional layer is within these ranges, the H-functional layer may have good hole injection and transport capabilities without a substantial increase in driving voltage.

In some embodiments, at least one of the HIL, HTL, and H-functional layer may include at least one of compounds of Formula 300 below and a compound of Formula 350 below:

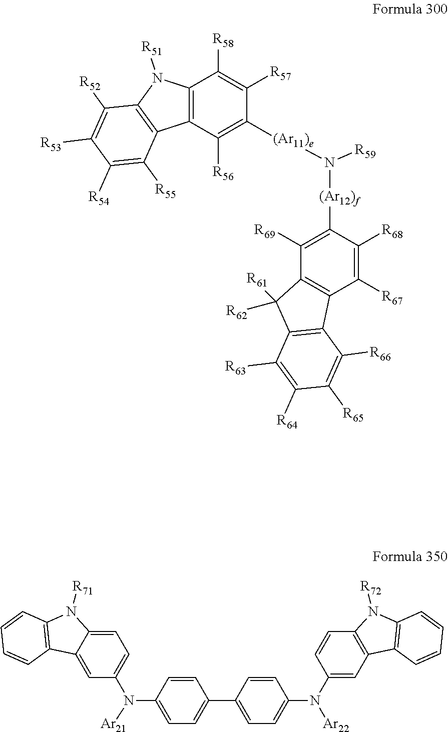

In Formulae 300 and 350, Ar₁₁, Ar₁₂, Ar₂₁ and Ar₂₂ may be each independently a substituted or unsubstituted C₅-C₆₀ arylene group.

In Formula 300, e and f may be each independently an integer of 0 to 5, or 0, 1, or 2. For example, e may be 1, and f may be 0, but they are not limited thereto.

In Formulae 300 and 350, R₅₁ to R₅₈, R₆₁ to R₆₉, R₇₁, and R₇₂ may be each independently hydrogen, deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstiuted C₆-C₆₀ aryl group, a substituted or unsubstituted C₅-C₆₀ aryloxy group, or a substituted or unsubstituted C₅-C₆₀ arylthio group.

In some embodiments, R₅₁ to R₅₈, R₆₁ to R₆₉, R₇₁, and R₇₂ may be each independently one of hydrogen; deuterium; a halogen atom; a hydroxyl group; a cyano group; a nitro group; an amino group; an amidino group; hydrazine; hydrazone; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, or the like); a C₁-C₁₀ alkoxy group (for example, a methoxy group, an ethoxy group, a propoxy group, a butoxy group, a pentoxy group, or the like); a C₁-C₁₀ alkyl group and a C₁-C₁₀ alkoxy group that are substituted with at least one of deuterium, a halogen atom, a hydroxyl group, a cyano group, a nitro group, an amino group, an amidino group, hydrazine, hydrazone, a carboxyl group or a salt thereof, a sulfonic acid group or a salt thereof, and a phosphoric acid group or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 300, R₅₉ may be one of a phenyl group, a naphthyl group, an anthryl group, a biphenyl group, a pyridyl group; and a phenyl group, a naphthyl group, an anthryl group, a biphenyl group, and a pyridyl group that are substituted with at least one of deuterium, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In an embodiment, the compound of Formula 300 may be a compound represented by Formula 300A below, but is not limited thereto:

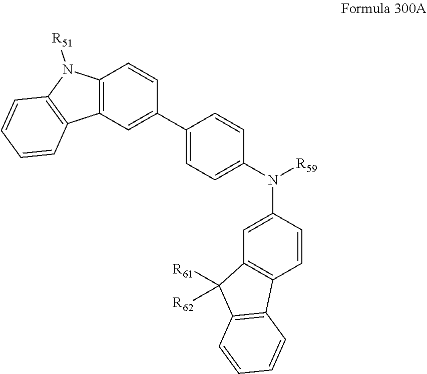

In Formula 300A, a detailed description of R₅₁, R₅₉, R₆₁ and R₆₂ may be as defined above.

In some non-limiting embodiments, at least one of the HIL, HTL, and H-functional layer may include at least one of compounds represented by Formulae 301 to 320 below, but is not limited thereto:

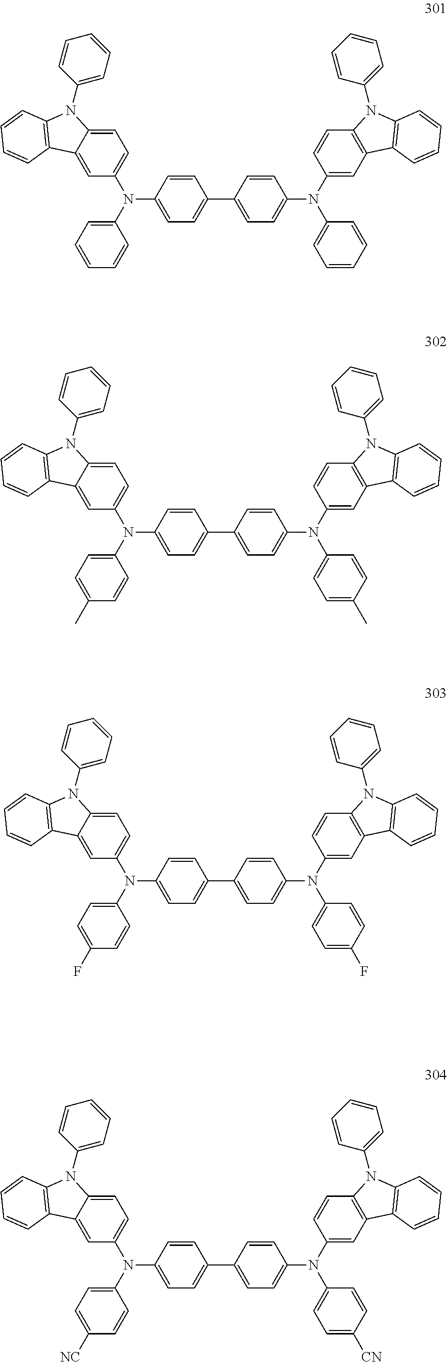 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

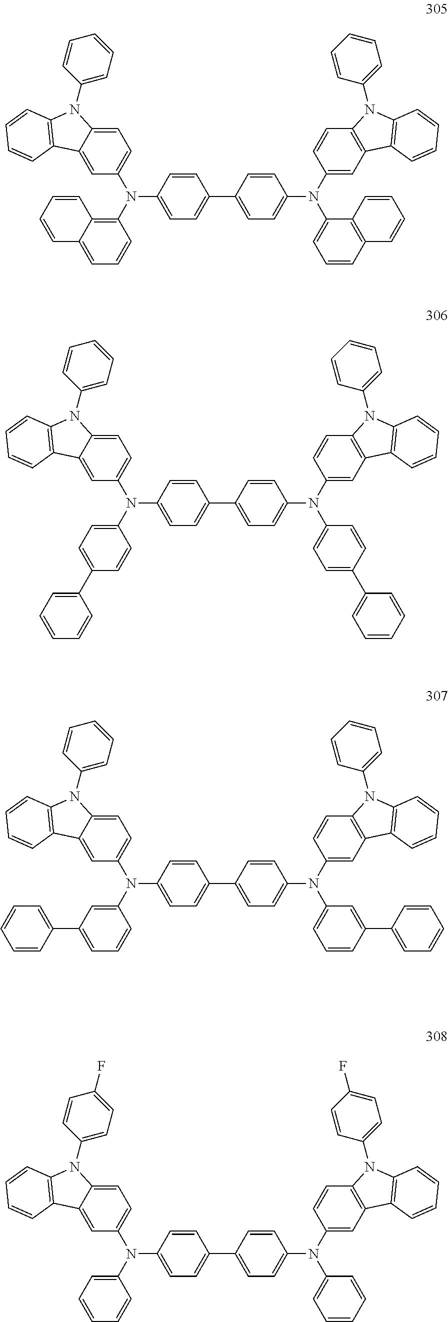 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

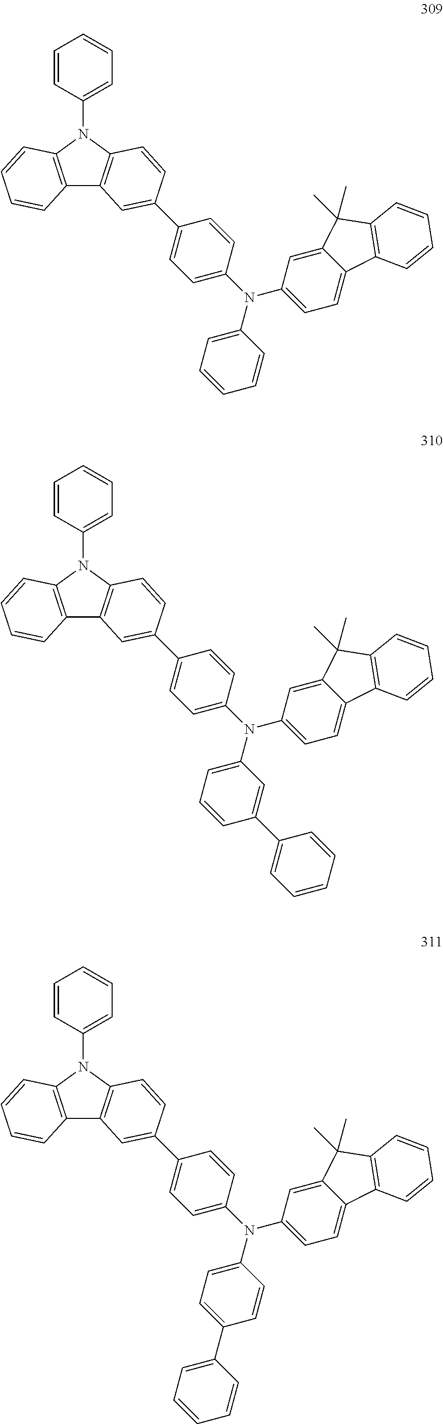 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

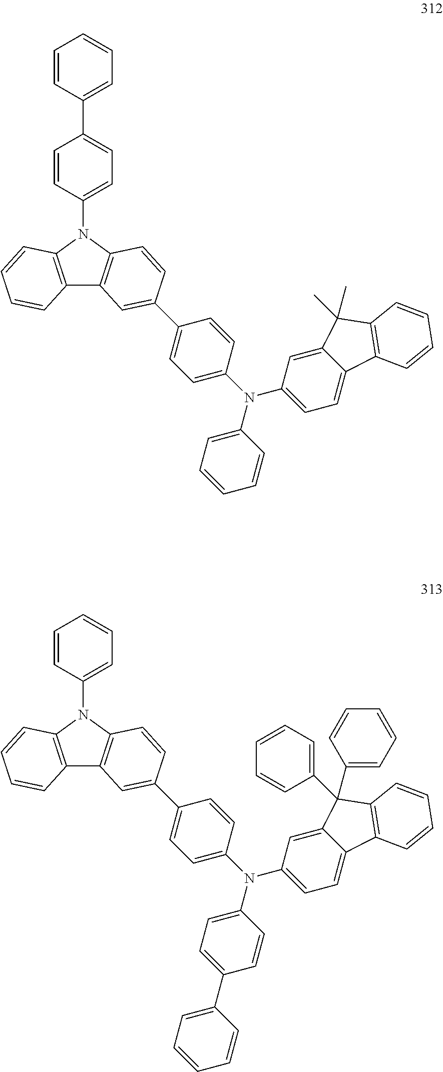 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

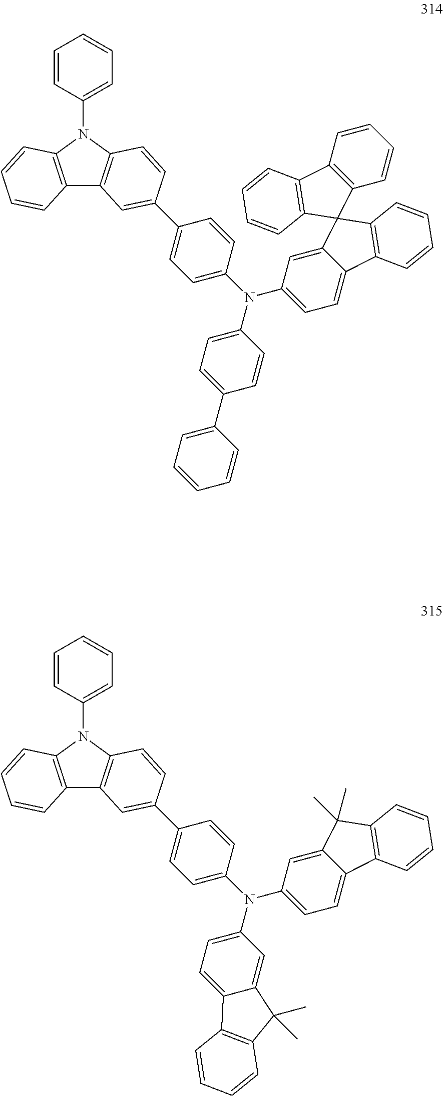 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

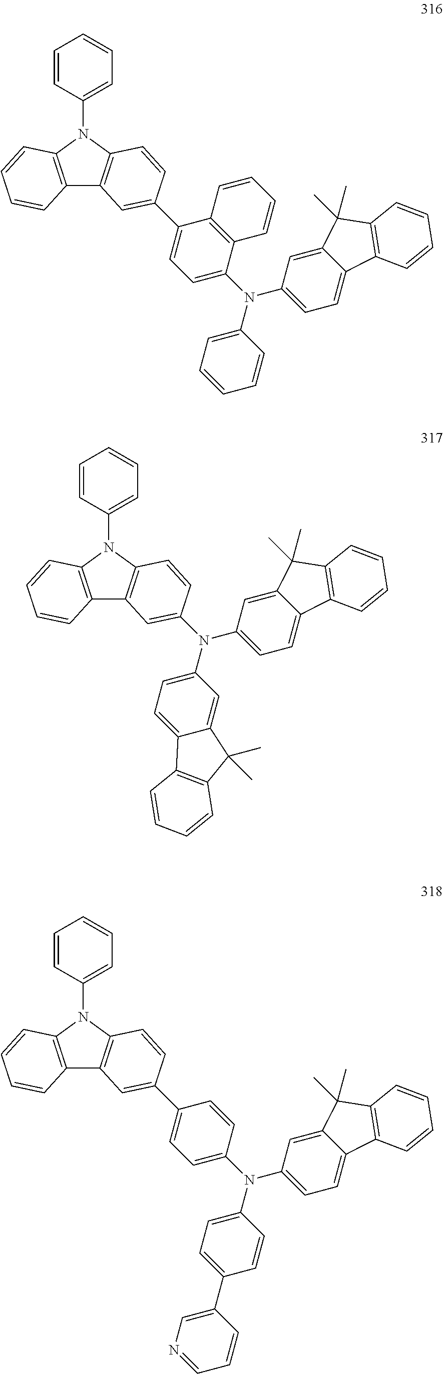 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

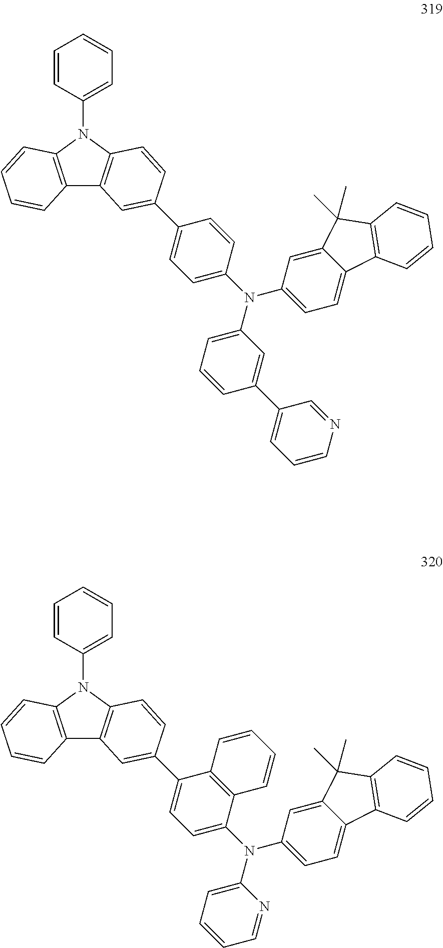 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccccn3)c3ccc(-c4ccc5c(c4)c4ccccc4n5-c4ccccc4)c4ccccc34)cc21]

At least one of the HIL, HTL, and H-functional layer may further include a charge-generating material for improved layer conductivity, in addition to a known hole injecting material, hole transport material, and/or material having both hole injection and hole transport capabilities as described above.

The charge-generating material may be, for example, a p-type dopant. The p-type dopant may be one of quinine derivatives, metal oxides, and compounds with a cyano group, but is not limited thereto. Non-limiting examples of the p-type dopant may be quinone derivatives such as tetracyanoquinonedimethane (TCNQ), 2,3,5,6-tetrafluoro-tetracyano-1,4-benzoquinonedimethane (F4-TCNQ), and the like; metal oxides such as tungsten oxide, molybdenum oxide, and the like; and cyano-containing compounds such as Compound 200 below.

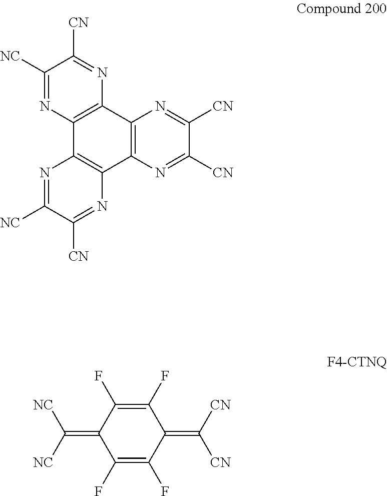 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, hole transport layer, or H-functional layer further includes a charge-generating material, the charge-generating material may be homogeneously dispersed or inhomogeneously distributed in the layer.

A buffer layer may be disposed between at least one of the HIL, HTL, H-functional layer, and the EML. The buffer layer may compensate for an optical resonance distance of light according to a wavelength of the light emitted from the EML, and thus may increase efficiency. The buffer layer may include any hole injecting material or hole transporting material that are widely known. In some other embodiments, the buffer layer may include the same material as one of the materials included in the HIL, HTL, and H-functional layer that underly the buffer layer.

Then, an EML may be formed on the HTL, H-functional layer, or buffer layer by vacuum deposition, spin coating, casting, Langmuir-Blodget (LB) deposition, or the like. When the EML is formed using vacuum deposition or spin coating, the deposition and coating conditions may be similar to those for the formation of the HIL, though the conditions for deposition and coating may vary according to the material that is used to form the EML.

The EML may be formed by using various known emission materials, and may be formed by a host and a dopant. As a dopant, a known fluorescent dopant and a known phosphorescent dopant may both be used.

For example, as a known host, Alga, CBP(4,4′-N,N′-dicarbazole-biphenyl), PVK(poly(n-vinylcabazole)), 9,10-di(naphthalene-2-yl)anthracene (ADN), TCTA, TPBI (1,3,5-tirs(N-phenylbenzimidazole-2-yl)benzene(1,3,5-tris (N-phenylbenzimidazole-2-yl)benzene)), TBADN (3-tert-butyl-9,10-di(naphth-2-yl)anthracene), E3, DSA(distyrylarylene), dmCBP (in Formula below), and Compounds 501 to 509 below may be used, but the host is not limited thereto.

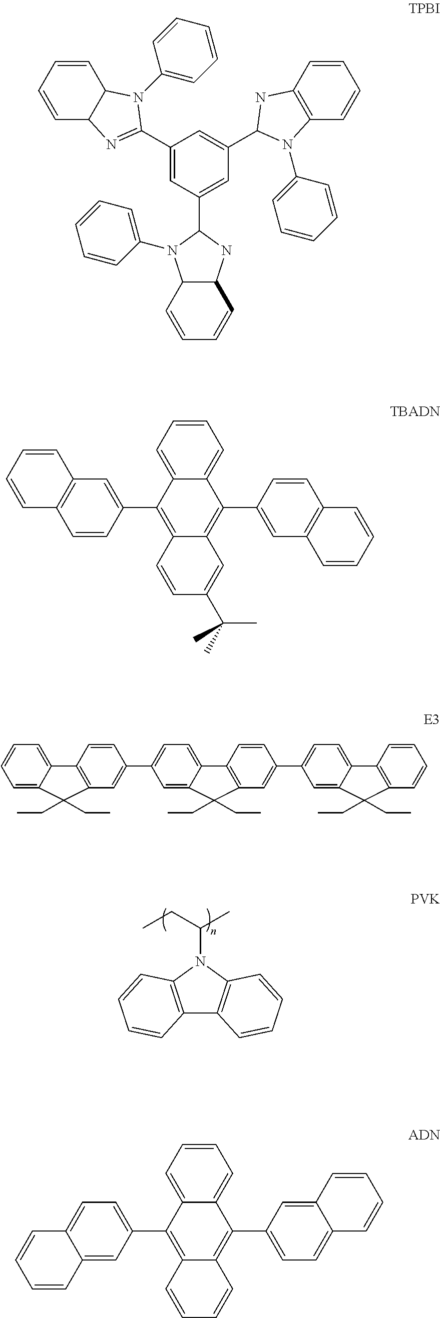

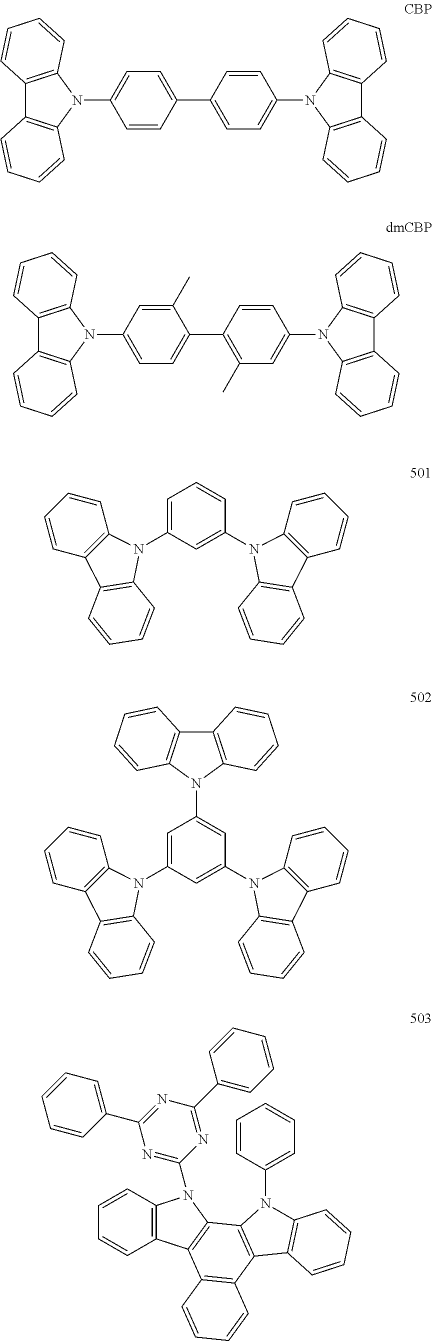 [SMILES: c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-c2nc(-c3ccccc3)nc(-n3c4ccccc4c4c5ccccc5c5c6ccccc6n(-c6ccccc6)c5c43)n2)cc1]

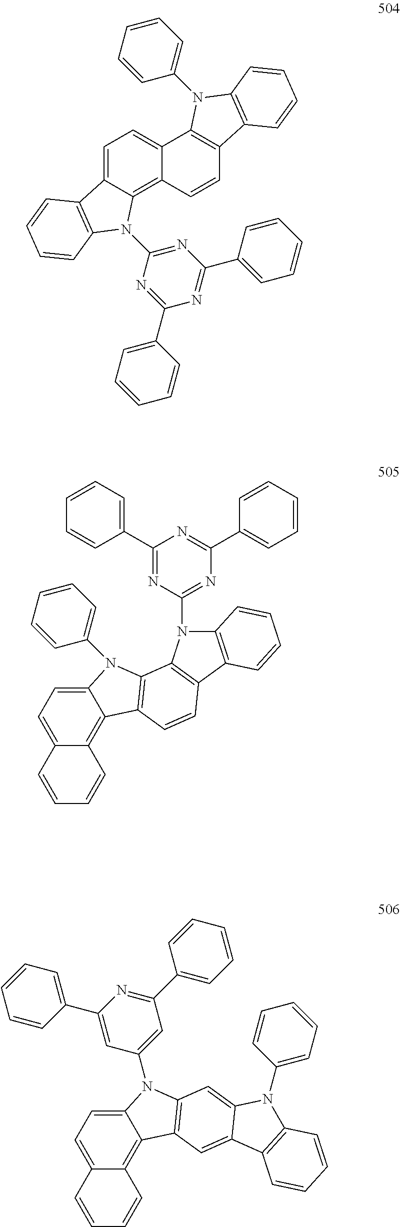 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

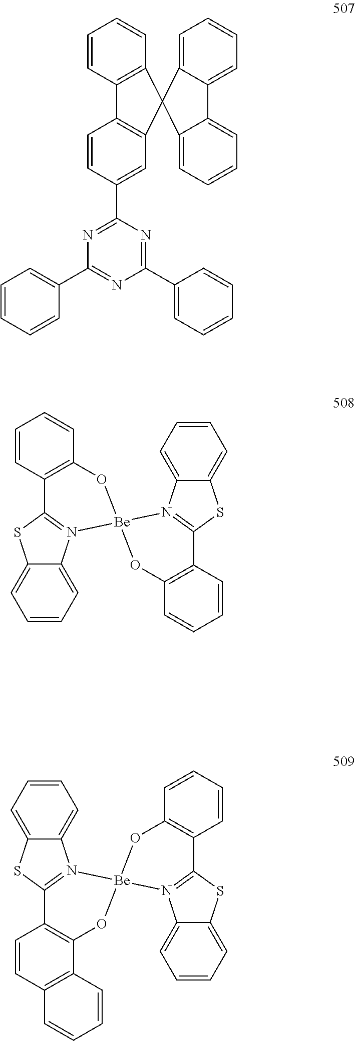

In some embodiments, an anthracene-based compound represented by Formula 400 below may be used as a host.

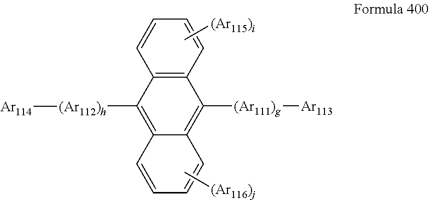

In Formula 400, Ar₁₁₁ and Ar₁₁₂ may be each independently a substituted or unsubstituted C₅-C₆₀ arylene group; Ar₁₁₃ to Ar₁₁₆ may be each independently a substituted or unsubstituted C₁-C₁₀ alkyl group, or a substituted or unsubstituted C₆-C₆₀ aryl group; and g, h, i and j may be each independently an integer of 0 to 4.

For example, in Formula 400, Ar₁₁₁ and Ar₁₁₂ may be a phenylene group, a naphthylene group, a phenanthrenyl group, or a pyrenyl group; or a phenylene group, a naphthylene group, a phenanthrenyl group, a fluorenyl group, or a pyrenylene group substituted with at least one of a phenyl group, a naphthyl group, and an anthryl group, but are not limited thereto.

In Formula 400, g, h, i, and j may be each independently 0, 1, or 2.

In Formula 400, Ar₁₁₃ to Ar₁₁₆ may be each independently a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; a phenyl group, a naphthyl group, and an anthryl group, a pyrenyl group, a phenanthrenyl group, and a fluorenyl group substituted with at least one of deuterium, a halogen atom, a hydroxyl group, a cyano group, a nitro group, an amino group, an amidino group, hydrazine, hydrazone, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, and a fluorenyl group; and

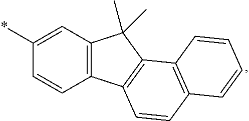 [SMILES: *c1ccc2c(c1)C(C)(C)c1c-2ccc2ccccc12]

but are not limited thereto.

For example, an anthracene-based compound represented by Formula 400 may be one of the compounds below, but is not limited thereto:

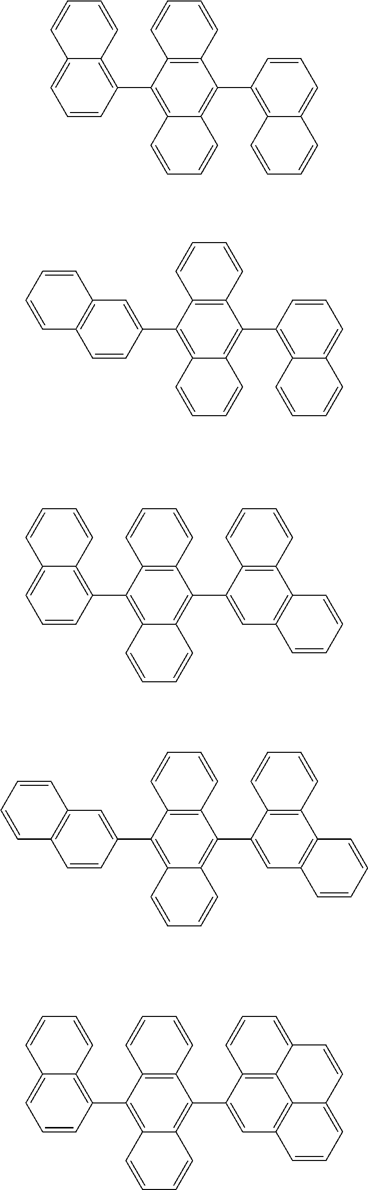

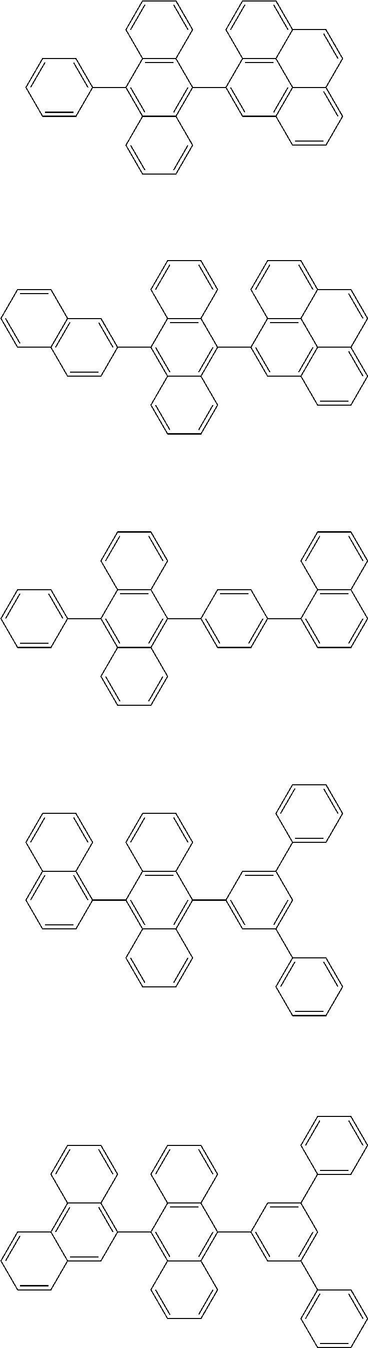

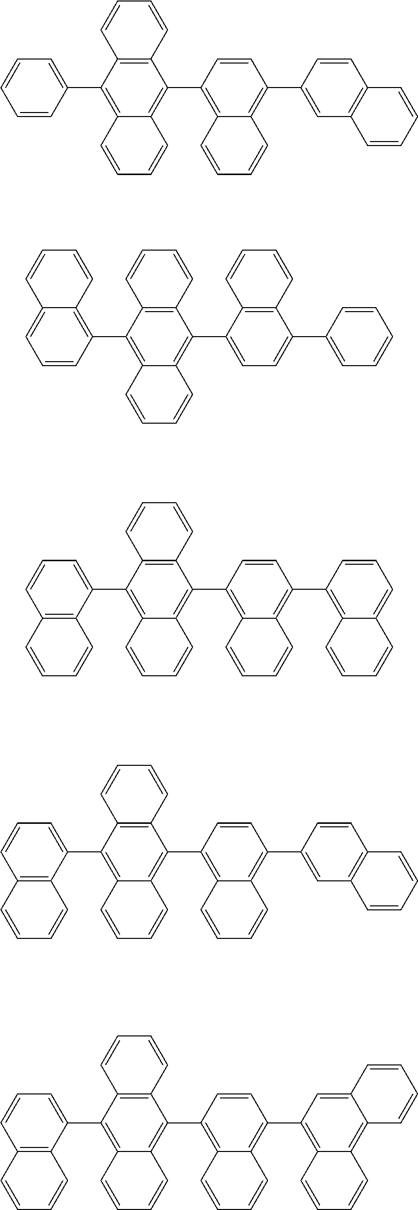

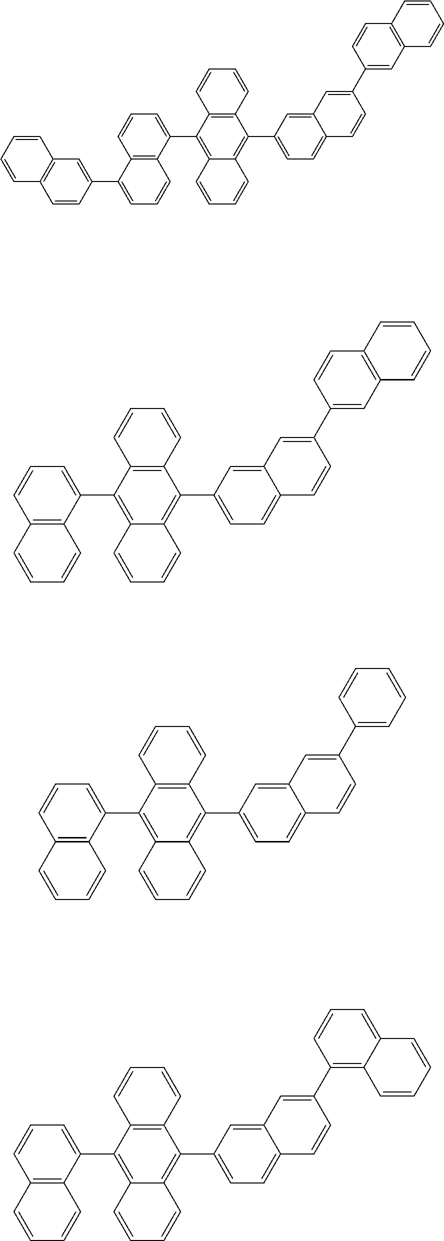

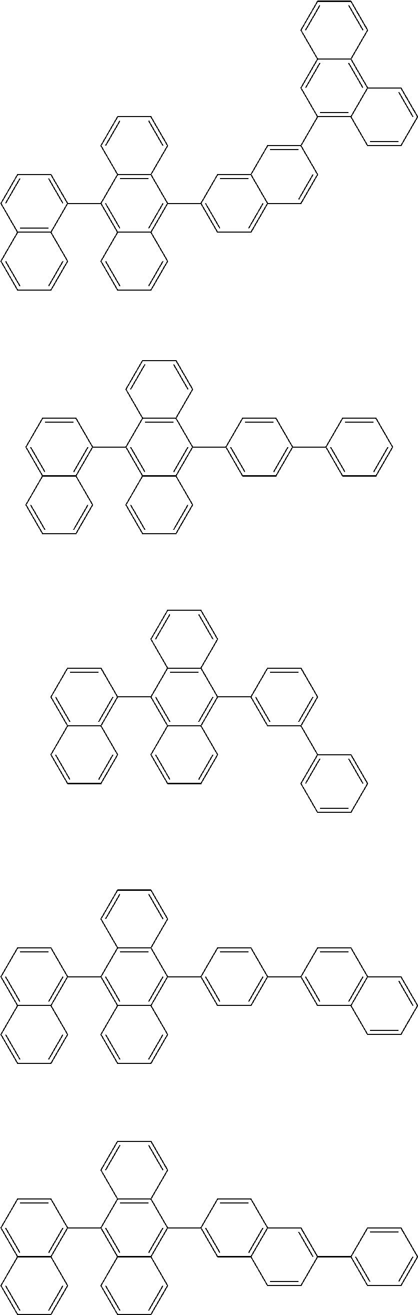

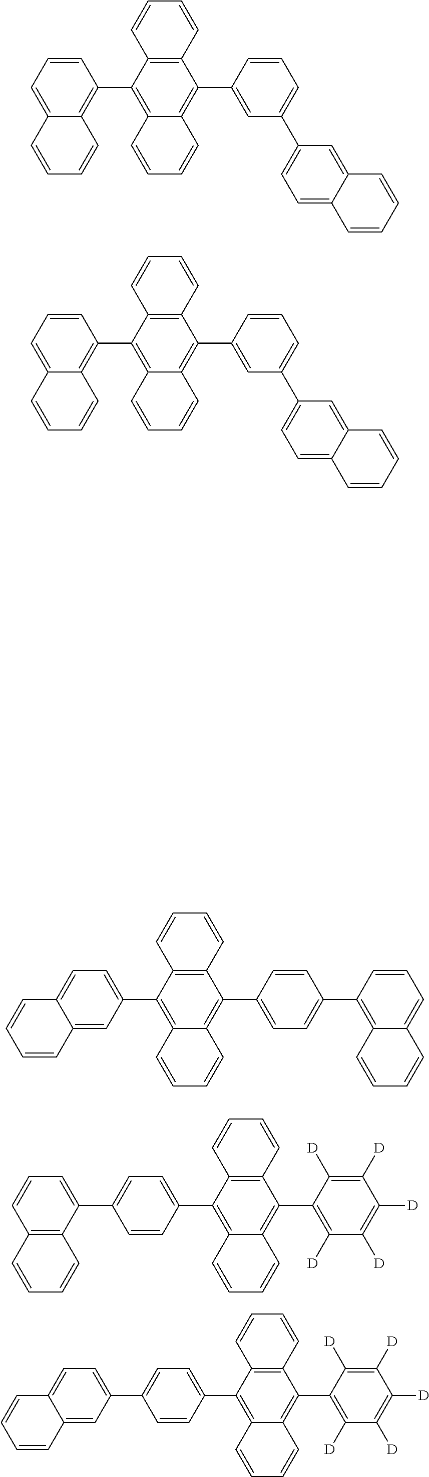

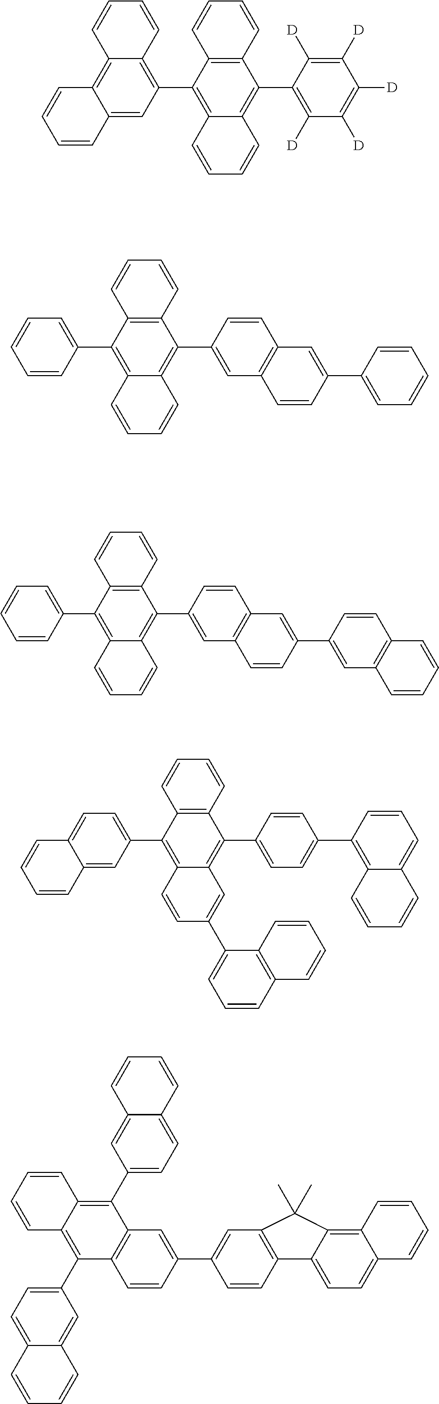

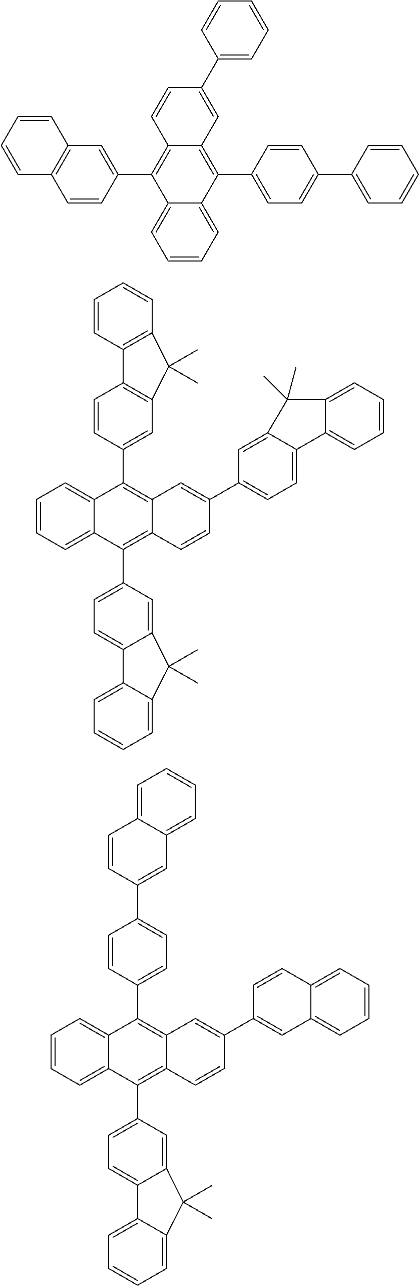

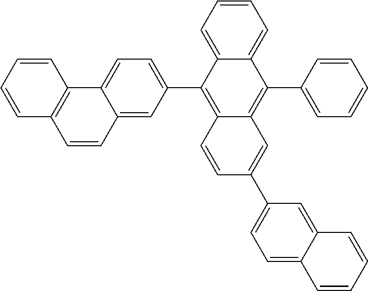 [SMILES: c1ccc(-c2c3ccccc3c(-c3ccc4c(ccc5ccccc54)c3)c3ccc(-c4ccc5ccccc5c4)cc23)cc1]

In other embodiments, an anthracene-based compound represented by Formula 401 below may be used as a host.

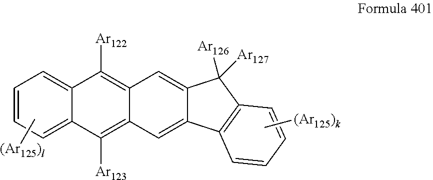

The descriptions of Ar₁₂₂ to Ar₁₂₅ in Formula 401 may be referred to in the above descriptions of Ar₁₁₃ in Formula 400.

In Formula 401, Ar₁₂₆ and Ar₁₂₇ may be each independently a C₁-C₁₀ alkyl group (for example, a methyl group, an ethyl group, or a propyl group).

In Formula 401, k and l may be each independently an integer of 0 to 4. For example, k and l may be 0, 1, or 2.

For example, the anthrecene-based compound represented by Formula 401 may be a compound of the compounds below, but is not limited thereto.

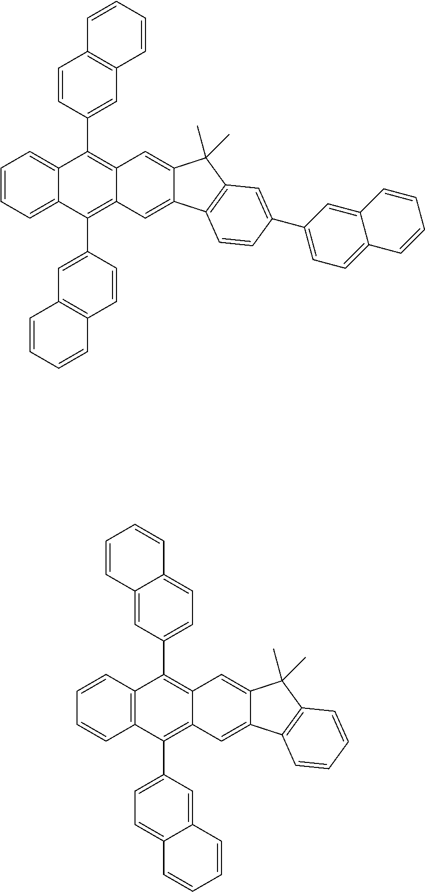

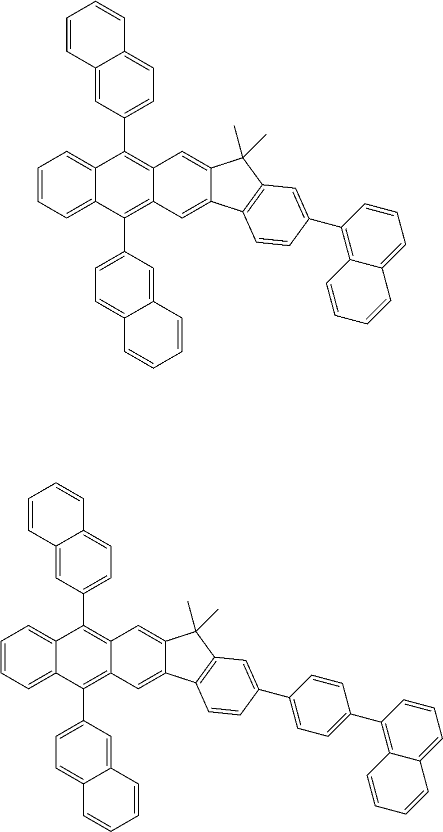

When the organic light-emitting device is a full color organic light-emitting device, the emission layer may be patterned into a red emission layer, a green emission layer, and a blue emission layer.

Meanwhile, at least one of the red emission layer, the green emission layer, and the blue emission layer may include a dopant below (ppy=phenylpyridine).

Non-limiting examples of the blue dopant may be compounds represented by the following formulae.

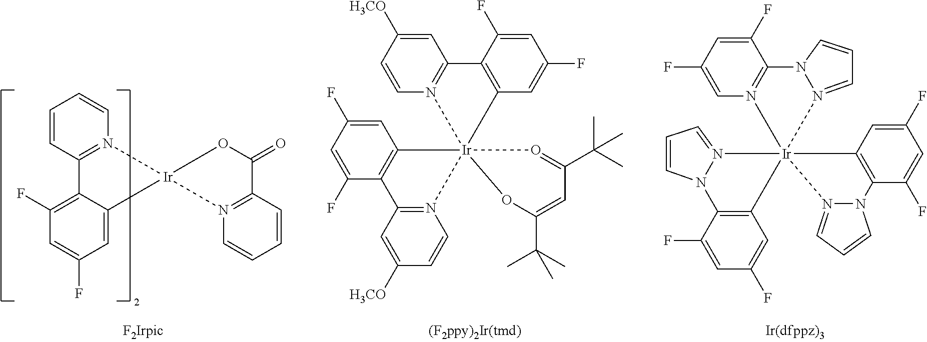

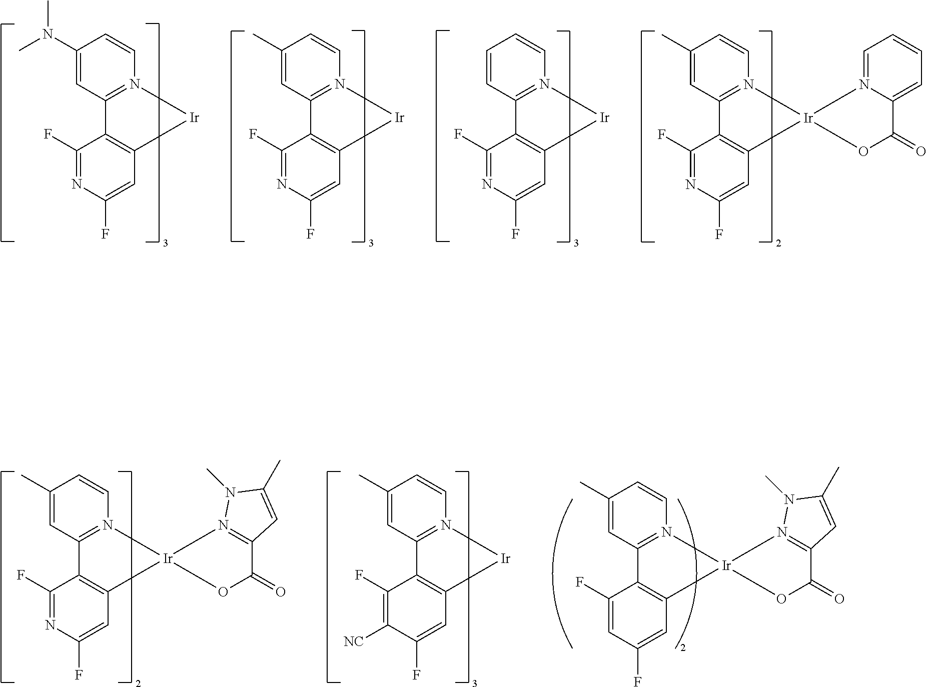

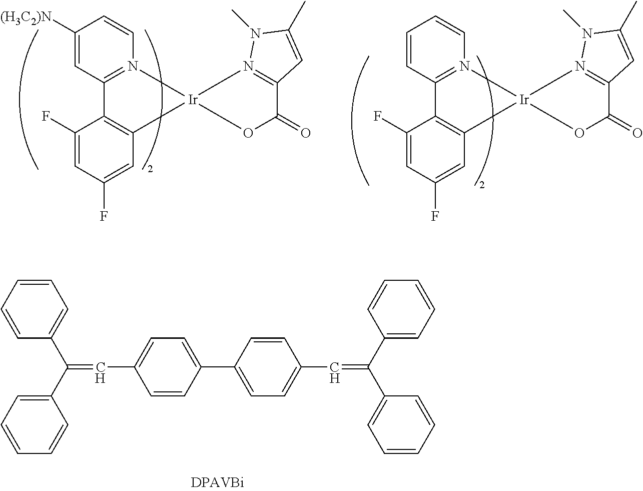

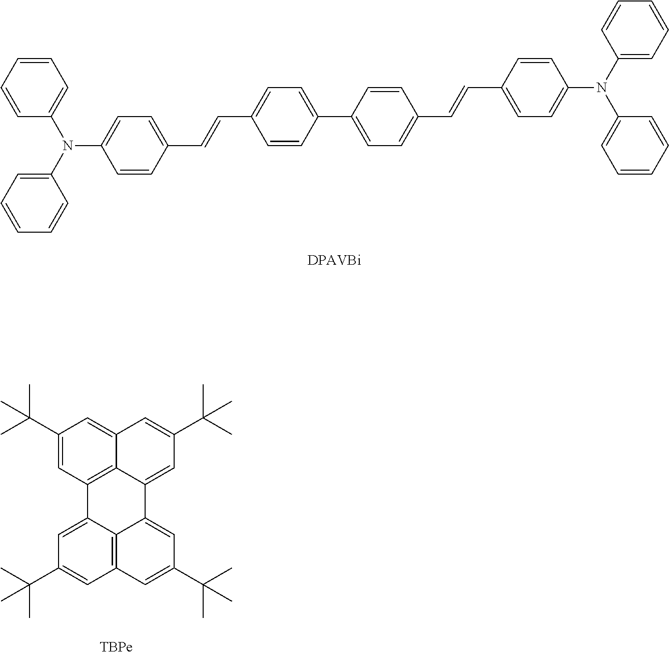

Non-limiting examples of the red dopant may be compounds represented by the following formulae.

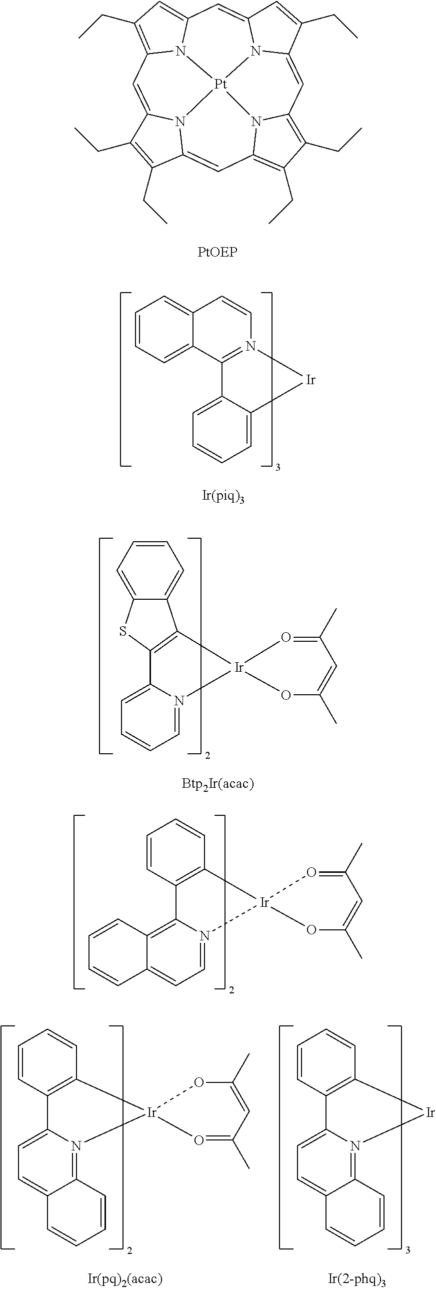

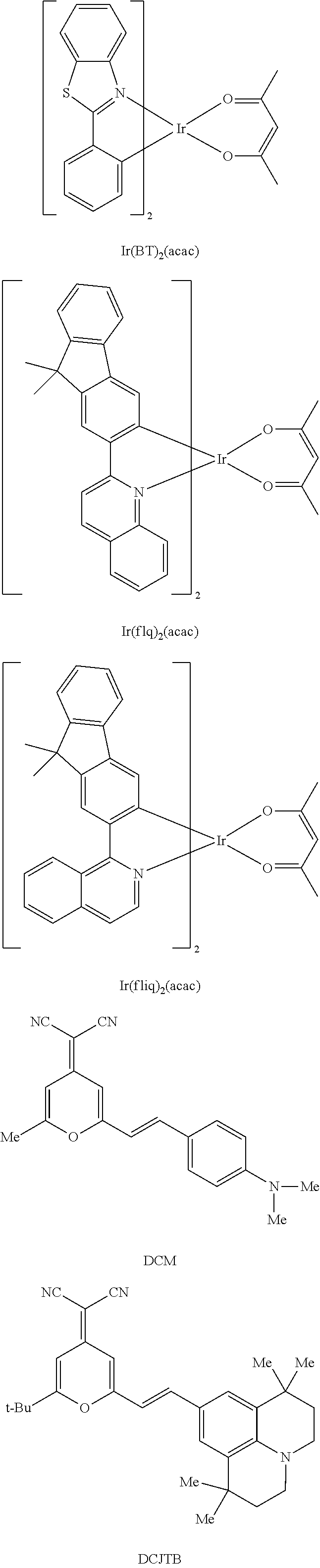

Non-limiting examples of the green dopant may be compounds represented by the following formulae.

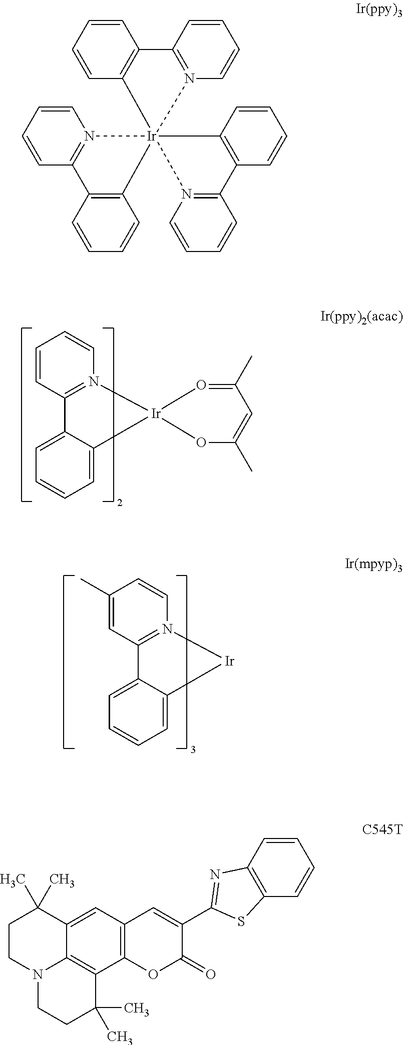

Meanwhile, a dopant that may be included in the EML may be a Pd-complex or Pt-complex as described below, but is not limited thereto.

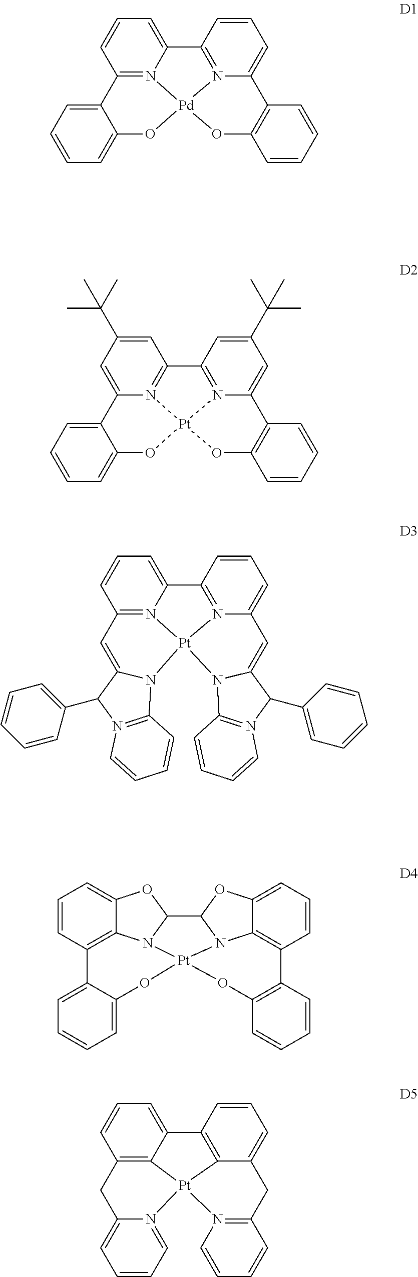

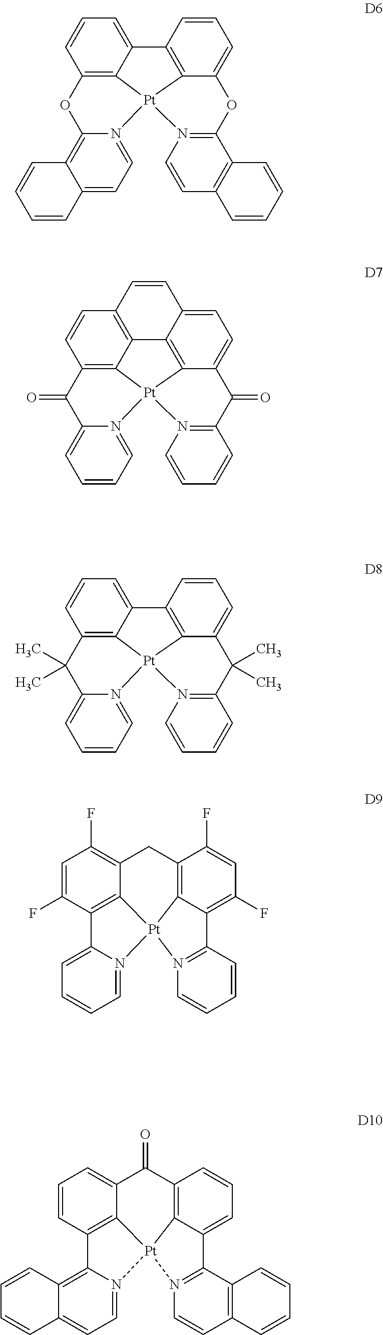

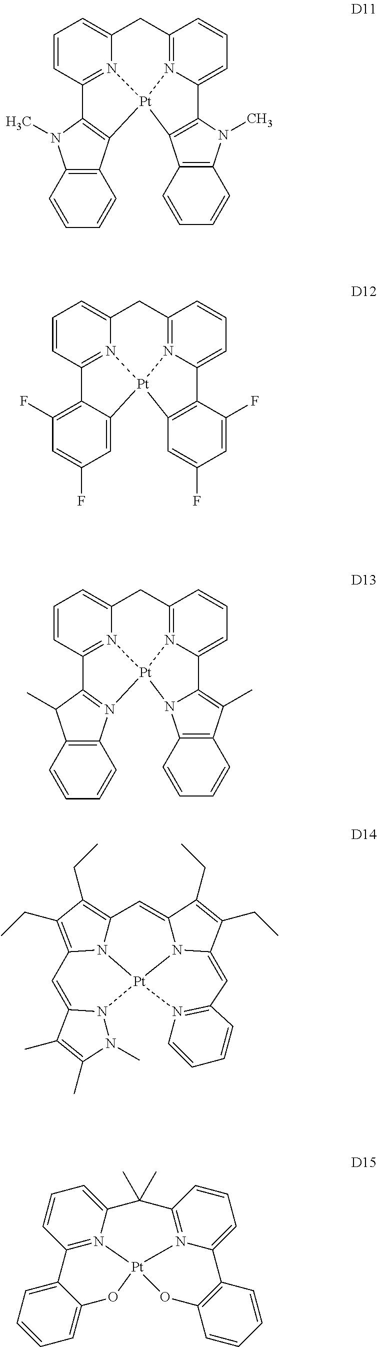

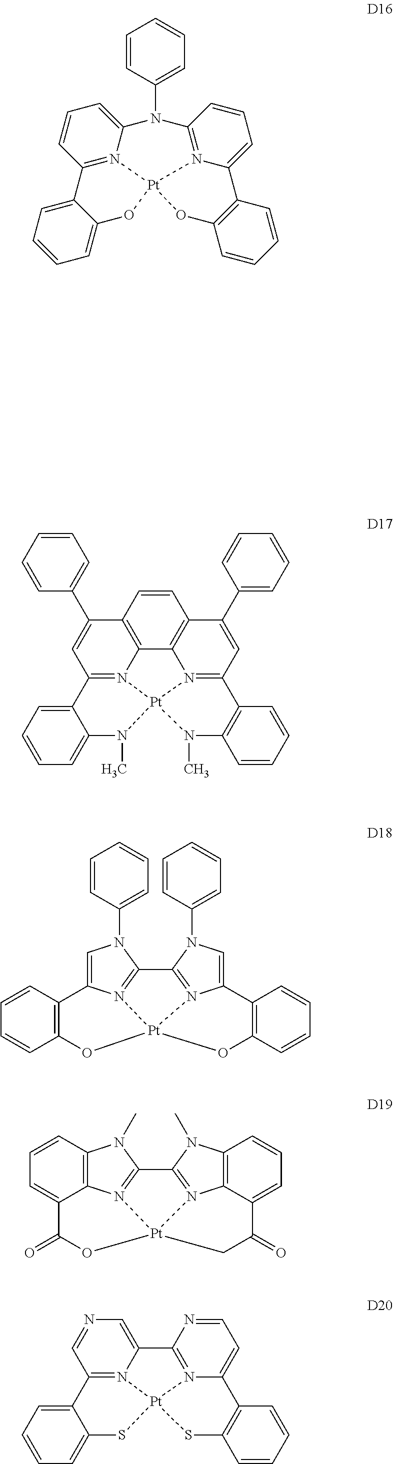

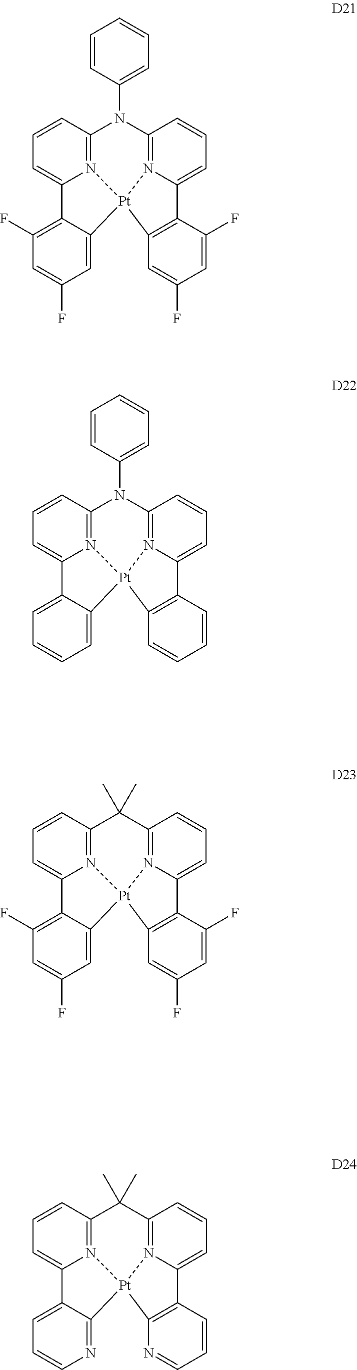

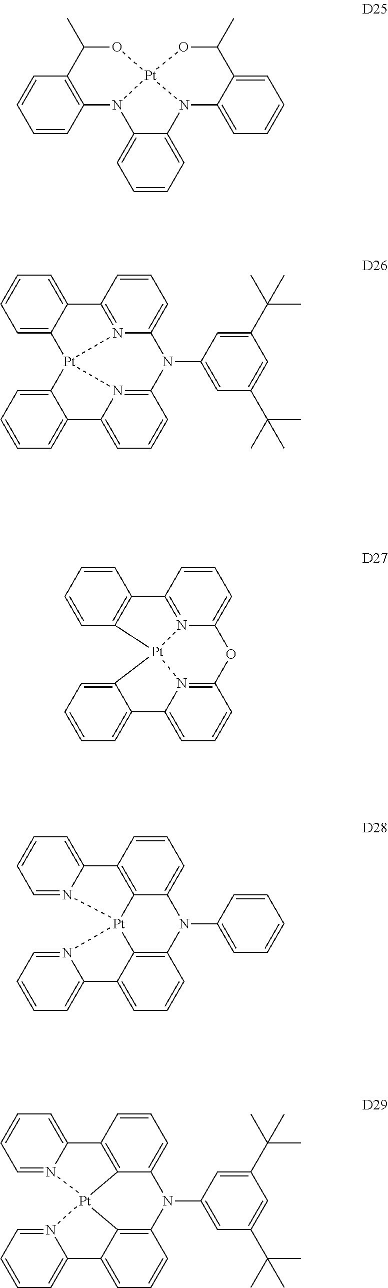

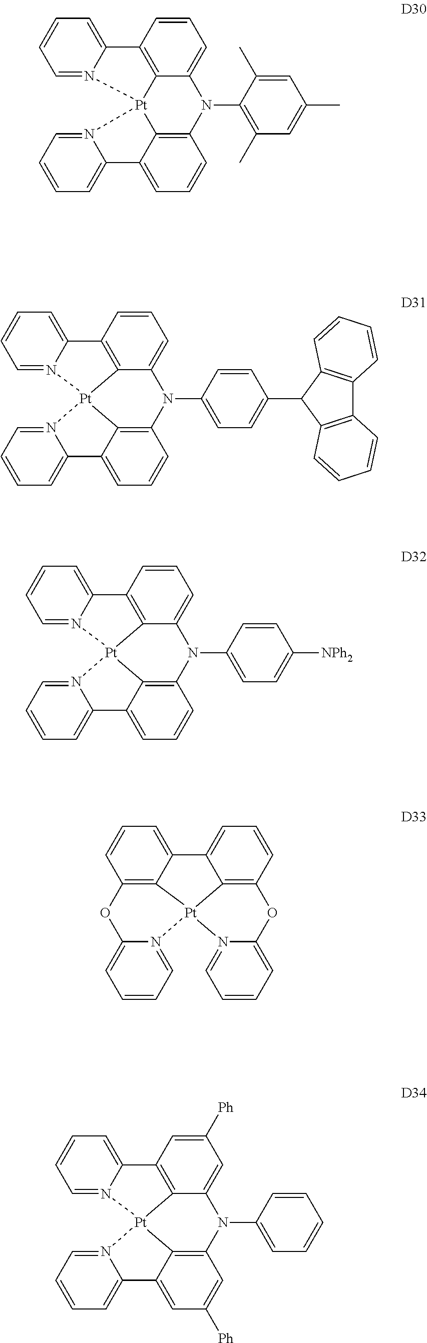

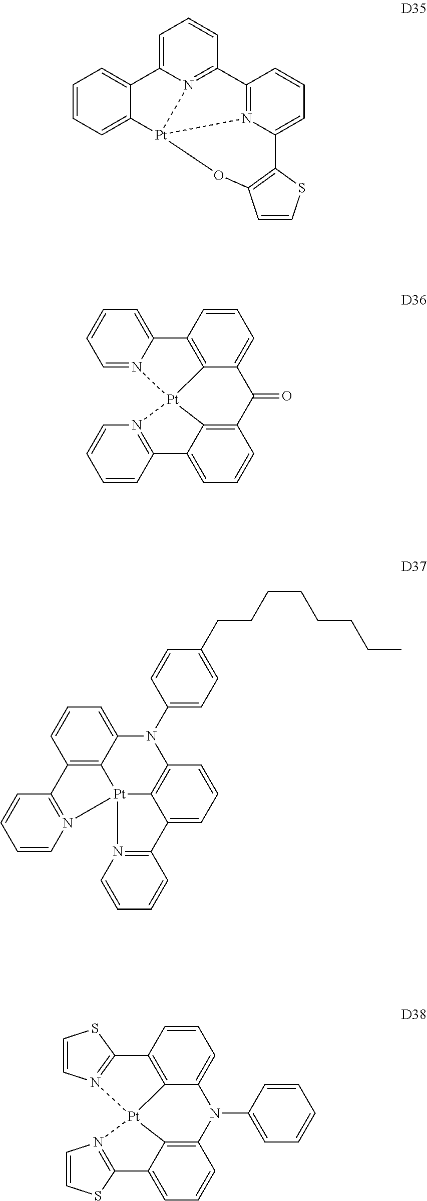

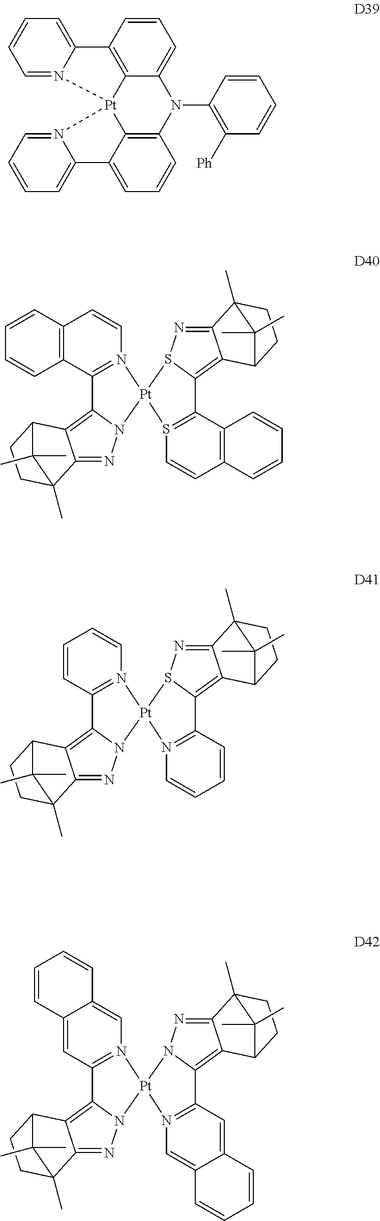

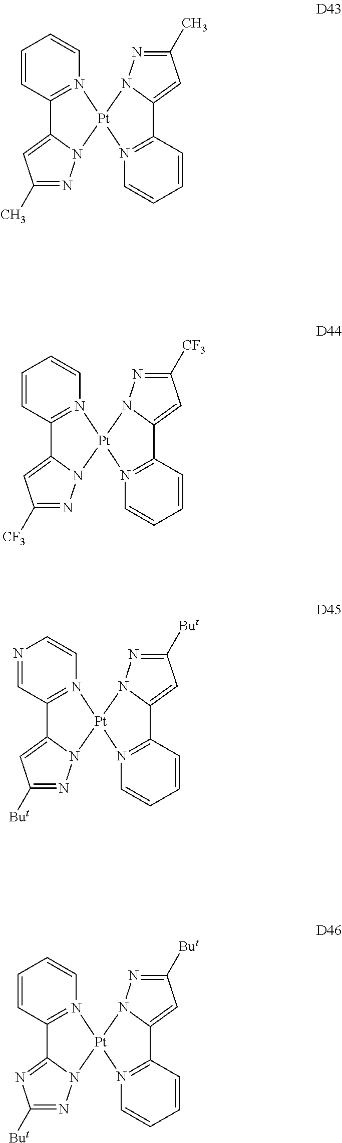

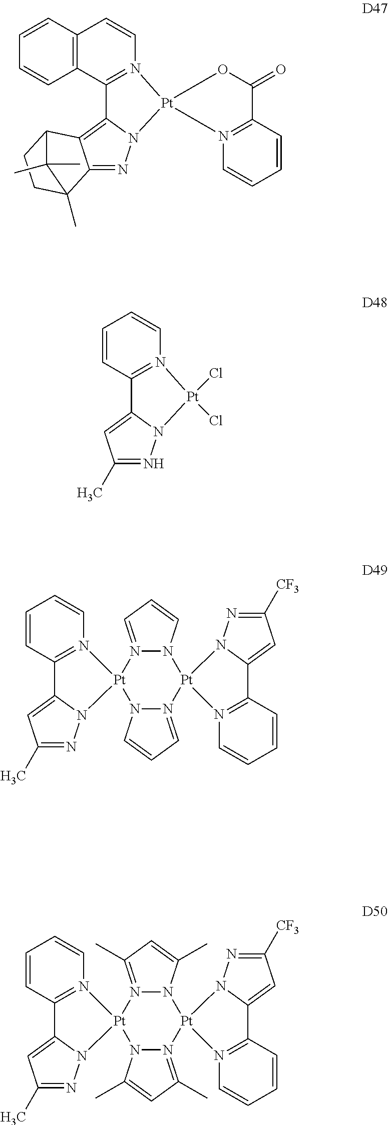

Non-limiting examples of the dopant that is used in the EML may be Os complexes represented by the following formulae.

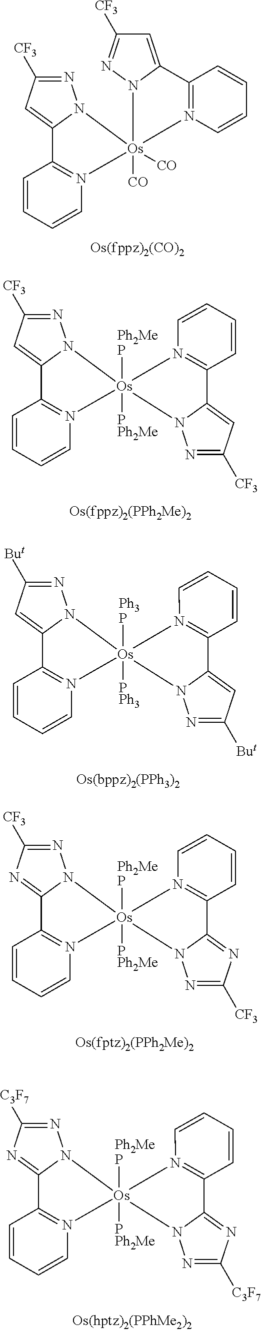

When the EML includes both a host and a dopant, the amount of the dopant may be from about 0.01 to about 15 parts by weight based on 100 parts by weight of the host. However, the amount of the dopant is not limited to this range.

The thickness of the EML may be from about 100 Å to about 1000 Å, and in some embodiments, may be from about 200 Å to about 600 Å. When the thickness of the EML is within these ranges, the EML may have good light emitting ability without a substantial increase in driving voltage.

Then, an ETL may be formed by any of a variety of methods, for example, vacuum deposition, spin coating, or casting. When the ETL is formed using vacuum deposition or spin coating, the deposition and coating conditions may be similar to those for the formation of the HIL, though the deposition and coating conditions may vary according to a material that is used to form the ETL.

The compound of Formula 1 above may be used as a material for the ETL. In some embodiments, when the compound of Formula 1 above is used in the HBL, any known electron transporting material that can stably transport electrons injected from an electron injecting electrode (cathode) may be used as a material for the ETL.

Non-limiting examples of materials for forming the ETL may be a quinoline derivative, such as tris(8-quinolinorate)aluminum (Alq3), TAZ, BAlq, beryllium bis(benzoquinolin-10-olate (Bebq2), 9,10-di(naphthalene-2-yl)anthracene (ADN), Compound 201, and Compound 202, but are not limited thereto.

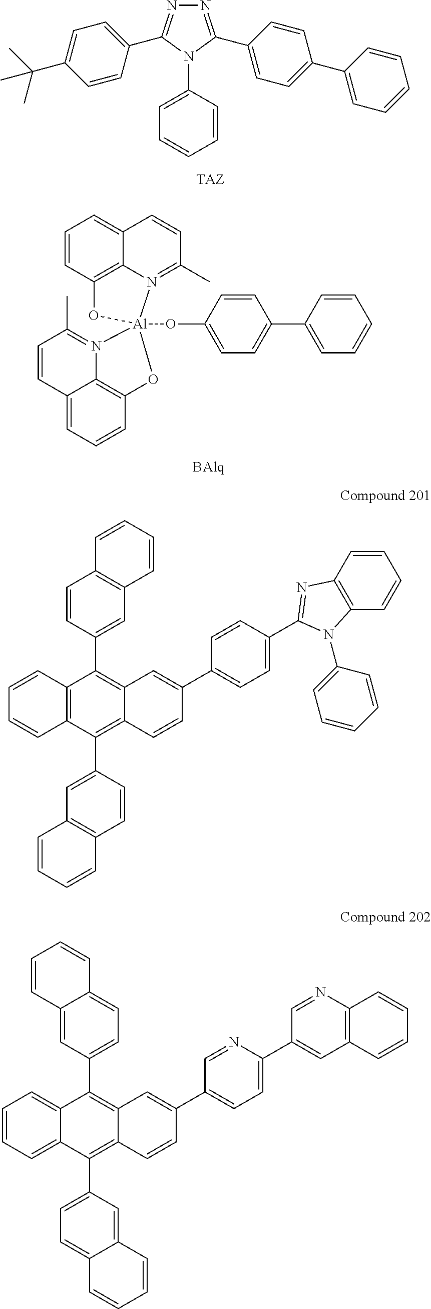

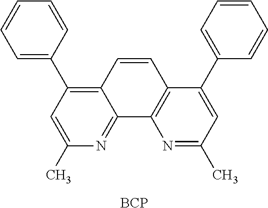 [SMILES: Cc1cc(-c2ccccc2)c2ccc3c(-c4ccccc4)cc(C)nc3c2n1 ; "BCP"]

A thickness of the ETL may be from about 100 Å to about 1,000 Å, and in some embodiments, may be from about 150 Å to about 500 Å. When the thickness of the ETL is within these ranges, the ETL may have satisfactory electron transporting ability without a substantial increase in driving voltage.

In some embodiments, the ETL may further include a metal-containing material, in addition to any known electron-transporting organic compound.

The metal-containing compound may include a lithium (Li) complex. Non-limiting examples of the Li complex are lithium quinolate (LiQ) and Compound 203 below.

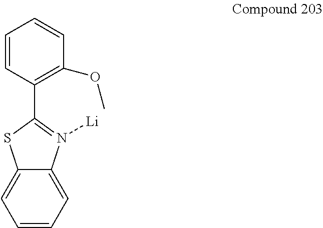

Then, an EIL, which facilitates injection of electrons from the cathode, may be formed on the ETL. Any suitable electron-injecting material may be used to form the EIL.

Non-limiting examples of the material for forming the EIL may be LiF, NaCl, CsF, Li₂O, and BaO, which are known in the art. The deposition and coating conditions for forming the EIL may be similar to those for the formation of the HIL, though the deposition and coating conditions may vary according to the material that is used to form the EIL.

A thickness of the EIL may be from about 1 Å to about 100 Å, and in some embodiments, may be from about 3 Å to about 90 Å. When the thickness of the EIL is within these ranges, the EIL may have satisfactory electron injection ability without a substantial increase in driving voltage.

The second electrode is disposed on the organic layer. The second electrode may be a cathode that is an electron injection electrode. A material for forming the second electrode may be a metal, an alloy, an electro-conductive compound, which have a low work function, or a mixture thereof. In this regard, the second electrode may be formed of lithium (Li), magnesium (Mg), aluminum (Al group, aluminum (Al group-lithium (Li), calcium (Ca), magnesium (Mg)-indium (In), magnesium (Mg)-silver (Ag), or the like, and may be formed as a thin film type transmission electrode. In some embodiments, to manufacture a top-emission light-emitting device, the transmission electrode may be formed of indium tin oxide (ITO) or indium zinc oxide (IZO).

Although the organic light-emitting device of FIG. 1 is described above, the present invention is not limited thereto.

When a phosphorescent dopant is also used in the EML, a hole blocking layer (HBL) may be formed between the ETL and the EML or between the E-functional layer and the EML by using vacuum deposition, spin coating, casting, Langmuir-Blodgett (LB) deposition, or the like, in order to prevent diffusion of triplet excitons or holes into an ETL.

When the HBL is formed using vacuum deposition or spin coating, the conditions for deposition and coating may be similar to those for the formation of the HIL, although the conditions for deposition and coating may vary according to the material that is used to form the HBL. The compound of Formula 1 above may be used as a material for the HBL.

A thickness of the HBL may be from about 20 Å to about 1000 Å, and in some embodiments, may be from about 30 Å to about 800 Å. When the thickness of the HBL is within these ranges, the HBL may have improved hole blocking ability without a substantial increase in driving voltage.

The organic light emitting device according to the present invention may be included in various flat display devices, for example, a passive matrix organic light emitting display device, and an active matrix organic light emitting display device. More particularly, when the organic light emitting device is included in the active matrix organic light emitting display device, the first electrode disposed on the substrate may electrically connect to the source electrode or to a drain electrode of the thin film transistor, as a pixel electrode. Also, the organic light emitting device may be included in a flat display device capable of displaying screens on both sides.

Also, the organic light emitting device according to an embodiment of the present invention may be formed through a deposition by using the compounds of Formula 1, or may be formed through wet corrosion by coating the compounds of Formula 1 according to an embodiment of the present inventive concept.

Hereinafter, the organic light emitting device according to an embodiment of the present invention will be described in greater detail with reference to the following Synthesis Examples and Examples. However, these examples are for illustrative purposes only and are not intended to limit the scope of the present invention.

### EXAMPLES

### Synthesis of Intermediate 1c

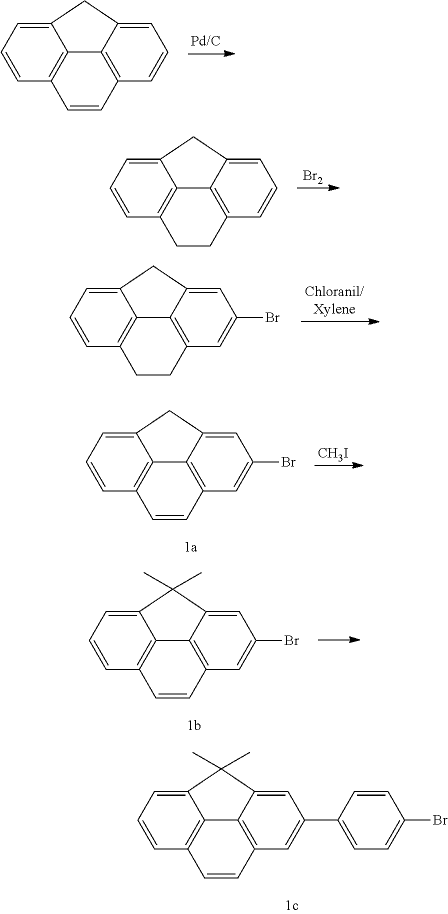

### 1) Synthesis of 8,9-Dihydro-4H-cyclopenta[def]phenanthrene)

In a Par reactor bottle, 10.0 g (52.6 mmol) of 4H-cyclopenta[def]phenanthrene) and 8.40 g of 5% Pd/C were dissolved in 70 mL of EtOH and then agitated for 24 hours at room temperature while maintaining the hydrogen pressure at 40 psi, to produce a reaction solution. Thereafter, the reaction solution was filtered and a solvent was evaporated to obtain 8.60 g of a white target material (yield rate 85.0%).

### 2) Synthesis of 2-Bromo-8,9-dihydro-4H-cyclopenta[def]phenanthrene)

8.5 g (44.2 mmol) of 2-Bromo-8,9-dihydro-4H-cyclopenta[def]phenanthrene) was dissolved in 80 mL of CCl₄, and 7.1 g (44.2 mmol) of Br₂ was added drop by drop at a temperature of 0° C. to produce a reaction solution. After agitating the reaction solution for 4 hours, 10% Na₂SO₃ was added to the reaction solution and an organic layer was separated. 9.6 g (yield rate 80%) of the target material was obtained by drying the organic layer with magnesium sulfate, evaporating a solvent, and recrystallizing the residue in n-hexane.

### 3) Synthesis of Intermediate 1a

9.3 g (34.3 mmol) of 2-Bromo-8,9-dihydro-4H-cyclopenta[def]phenanthrene) and o-Chloranil (8.8 g, 36.0 mmol) were dissolved in 70 mL xylene and then agitated for 72 hours at a temperature of 110° C. to produce a reaction solution. After cooling the reaction solution at room temperature, a product obtained by evaporating a solvent was isolated and purified by a silica gel column chromatography to obtain 7.48 g (yield rate 81%) of an Intermediate 1a. The Intermediate 1a was observed through ¹H NMR and MS/FAB. C₁₅H₉Br: calc. 267.99. found 267.97.

¹H NMR (CDCl₃, 400 MHz) 7.98 (2H, s), 7.79 (2H, s), 7.73 (2H, s), 6.94 (dd, 1H), 4.28 (2H, s).

### 4) Synthesis of Intermediate 1b

7.3 g (27.1 mmol) of the Intermediate 1a, t-BuOK (73.2 g, 216.8 mmol), and 60 mL of HMPA were dissolved in 60 mL of DMSO and then agitated for 1 hour at room temperature to produce a reaction solution. In the reaction solution, CH₃I (30.6 g, 216.8 mmol) was added drop by drop at a temperature of 0° C., agitated for 30 minutes, 40 mL of water was added, and then extracted three times by using 70 mL of methylene chloride. Residues obtained by drying organic layers by using magnesium sulfate and by evaporating a solvent were isolated and purified by using the silica gel column chromatography to obtain 6.3 g of Intermediate 1b (yield rate 78%). The Intermediate 1b was observed through ¹H NMR and MS/FAB. C₁₇H₁₃Br: calc. 296.02. found 296.05.

¹H NMR (CDCl₃, 400 MHz) 7.98 (2H, s), 7.79 (2H, s), 7.73 (2H, s), 6.94 (dd, 1H), 1.93 (m, 6H).

### 5) Synthesis of Intermediate 1c

6.0 g (20.2 mmol) of Intermediate 1b, 5.7 g (20.2 mmol) of 2-(4-bromophenyl)-4,4,5,5-tetramethyl-[1,3,2]dioxaborolane, 1.17 g (1.0 mmol) of Pd(PPh₃)₄, and 8.4 g (60.6 mmol) K₂CO₃ were dissolved in 60 mL of THF and 30 mL of H₂O and then agitated for 12 hours at a temperature of 80° C. to produce a reaction solution. After cooling the reaction solution to room temperature, the reaction solution was extracted three times by using 30 mL of water and 30 mL of ethylacetate. Residues obtained by drying organic layers by using magnesium sulfate and evaporating a solvent were isolated and purified by using the silica gel column chromatography to obtain 6.40 g of Intermediate 1c (yield rate 85%). The Intermediate 1c was observed through ¹H NMR and MS/FAB. C₂₃H₁₇Br: calc. 373.05. found 373.06.

¹H NMR (CDCl₃, 400 MHz) 8.11 (d, 1H), 7.75-7.71 (m, 2H), 7.66-7.62 (m, 3H), 7.59-7.56 (m, 3H), 7.50 (d, 1H), 7.31 (t, 1H), 1.83 (s, 6H).

### Synthesis of Compound 39

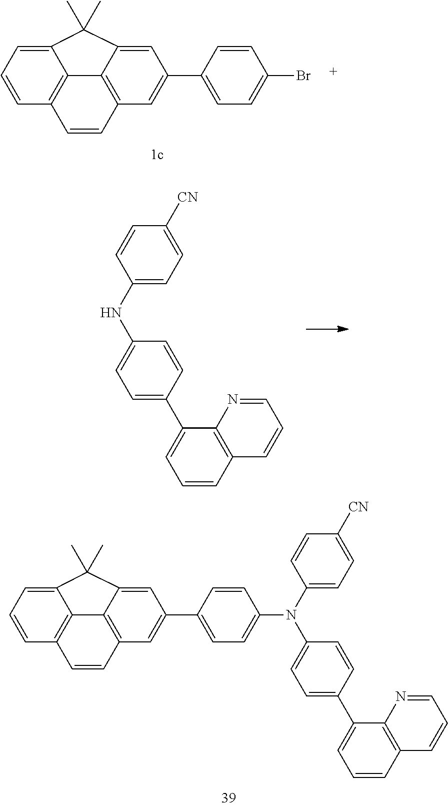 [SMILES: CC1(C)c2cccc3ccc4cc(-c5ccc(Br)cc5)cc1c4c23 ; N#Cc1ccc(Nc2ccc(-c3cccc4cccnc34)cc2)cc1 ; CC1(C)c2cccc3ccc4cc(-c5ccc(N(c6ccc(C#N)cc6)c6ccc(-c7cccc8cccnc78)cc6)cc5)cc1c4c23]

4.11 g (11.0 mmol) of Intermediate 1c, 3.53 g (11.0 mmol) of 4-(4-quinoline-8-yl-phenylamino)benzonitrile, 0.21 g (0.22 mmol) of Pd₂(dba)₃, 0.044 g (0.22 mmol) of P(tBu)₃, and 1.58 g (16.5 mmol) NaOtBu were dissolved in 70 mL of toluene and then agitated for 4 hours at a temperature of 80° C. After cooling the reaction solution to room temperature, 40 mL of water was added to the reaction solution, and then extracted three times by using 50 mL of ethylether. Residues obtained by drying organic layers by using magnesium sulfate and evaporating a solvent were isolated and purified by using the silica gel column chromatography to obtain 5.06 g of Compound 39 (yield rate 75%). The compound was observed through ¹H NMR and MS/FAB. C₄₅H₃₁N₃: calc. 613.25. found 613.26.

### Synthesis of Compound 47

4.65 g of Compound 47 (yield rate 72%) was synthesized in the same manner as in Synthesis of Compound 39, except that 2-(6-bromo-naphthalene-2-yl)-4,4,5,5-tetramethyl-[1,3,2]dioxaborolane was used instead of 2-(4-bromophenyl)-4,4,5,5-tetramethyl-[1,3,2]dioxaborolane in the Synthesis of Intermediate 1c and that 4-(naphthalene-1-ylamino)benzonitrile was used instead of 4-(4-quinoline-8-yl-phenylamino)benzonitrile in the synthesis of Compound 39. The compound was observed through ¹H NMR and MS/FAB. C₄₄H₃₀N₂: calc. 586.24. found 586.22.

### Synthesis of Compound 51

5.75 g of Compound 51 (yield rate 73%) was synthesized in the same manner as in Synthesis of Compound 39, except that 2-(6-bromo-naphthalene-2-yl)-4,4,5,5-tetramethyl-[1,3,2]dioxaborolane was used instead of 2-(4-bromophenyl)-4,4,5,5-tetramethyl-[1,3,2]dioxaborolane in the Synthesis of Intermediate 1c and that (3,5-dipyridine-3-ylphenyl)-naphthalene-1-ylamine was used instead of 4-(4-quinoline-8-yl-phenylamino)benzonitrile in the synthesis of Compound 39. The compound was observed through ¹H NMR and MS/FAB. C₅₃H₃₇N₃: calc. 715.30. found 715.32.

### Synthesis of Compound 54

5.62 g of Compound 54 (yield rate 77%) was synthesized in the same manner as in Synthesis of Compound 54, except that 2-(4-bromo-naphthalene-1-yl)-4,4,5,5-tetramethyl-[1,3,2]dioxaborolane was used instead of 2-(4-bromophenyl)-4,4,5,5-tetramethyl-[1,3,2]dioxaborolane in the Synthesis of Intermediate 1c. The compound was observed through ¹H NMR and MS/FAB. C₄₉H₃₃N₃: calc. 663.27. found 663.29.

### Synthesis of Compound 62

5.98 g of Compound 62 (yield rate 80%) was synthesized in the same manner as in Synthesis of Compound 39, except that 2-(7-bromo-9,9-dimethyl-9H-fluorene-2-yl)-4,4,5,5-tetramethyl-[1,3,2]dioxaborolane was used instead of 2-(4-bromophenyl)-4,4,5,5-tetramethyl-[1,3,2]dioxaborolane in the Synthesis of Intermediate 1c and that 4-(4-pyridine-3-yl-phenylamino)benzonitrile was used instead of 4-(4-quinoline-8-yl-phenylamino)benzonitrile in the synthesis of Compound 39. The compound was observed through ¹H NMR and MS/FAB. C₅₀H₃₇N₃: calc. 679.30. found 679.28.

### Synthesis of Intermediate 2c

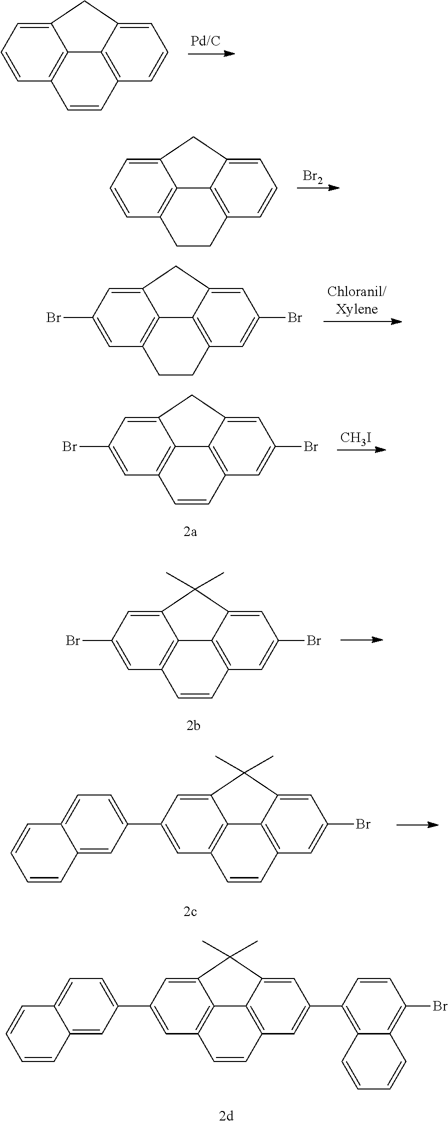

### 1) Synthesis of 2,6-dibromo-8,9-dihydro-4H-cyclopenta[def]phenanthrene

8.9 g of a target material (yield rate 57%) was synthesized in the same manner as in the Synthesis of Intermediates 1(2), except that Br₂ (14.2 g, 88.4 mmol) was used in the Synthesis of Intermediates 1 (2).

### 2) Synthesis of Intermediate 2a

6.8 g of an Intermediate 2a (yield rate 80%) was synthesized in the same manner as in the Synthesis of Intermediates 1 (3), except that 2,6-dibromo-8,9-dihydro-4H-cyclopenta[def]phenanthrene was used instead of 2-bromo-8,9-dihydro-4H-cyclopenta[def]phenanthrene in the Synthesis of Intermediates 1 (3). The Intermediate 2a was observed through ¹H NMR and MS/FAB. C₁₅H₈Br₂: calc. 345.90. found 345.92.

¹H NMR (CDCl₃, 400 MHz) 7.98 (2H, s), 7.79 (2H, s), 7.73 (2H, s), 4.28 (2H, s)

### 3) Synthesis of Intermediate 2b

5.8 g of Intermediate 2b (yield rate 79%) was synthesized in the same manner as in the Synthesis of Intermediate 1 (4), except that Intermediate 2a was used instead of Intermediate 1a in the Synthesis of Intermediate (4). The Intermediate 2b was observed through ¹H NMR and MS/FAB. C₁₅H₈Br₂: calc. 345.90. found 345.92.

¹H NMR (CDCl₃, 400 MHz) 7.98 (2H, s), 7.79 (2H, s), 7.73 (2H, s), 1.93 (s, 6H)

### 4) Synthesis of Intermediate 2c

5.64 g (15.0 mmol) of Intermediate 2b, 3.81 g (15.0 mmol) of 4,4,5,5-tetramethyl-2-naphthalene-2-yl-[1,3,2]dioxaborolane, 0.87 g (0.75 mmol) of Pd(PPh₃)₄, and 6.22 g (45.0 mmol) K₂CO₃ were dissolved in 60 mL of THF and 30 mL of H₂O and then agitated for 12 hours at a temperature of 80° C. to produce a reaction solution. After cooling the reaction solution to room temperature, the reaction solution was extracted three times by using 30 mL of water and 30 mL of ethylacetate. Residues obtained by drying organic layers by using magnesium sulfate and evaporating a solvent were isolated and purified by using the silica gel column chromatography to obtain 5.21 g of Intermediate 2c (yield rate 82%). The Intermediate 2c was observed through ¹H NMR and MS/FAB. C₂₇H₁₉Br: calc. 422.07. found 422.09.

¹H NMR (CDCl₃, 400 MHz) 8.22 (d, 1H), 8.05 (d, 1H), 8.00-7.92 (m, 5H), 7.87-7.75 (m, 2H), 7.62-7.57 (m, 2H), 7.30-7.26 (m, 1H), 7.22 (d, 1H), 1.90 (s, 6H)

### 4) Synthesis of Intermediate 2d

5.20 g (12.3 mmol) of Intermediate 2c, 4.10 g (12.3 mmol) of 2-(4-bromo-naphthalene-1-yl)-4,4,5,5-tetramethyl-[1,3,2]dioxaborolane, 0.71 g (0.62 mmol) of Pd(PPh₃)₄, and 4.90 g (36.9 mmol) K₂CO₃ were dissolved in 60 mL of THF and 30 mL of H₂O and then agitated for 12 hours at a temperature of 80° C. to produce a reaction solution. After cooling the reaction solution to room temperature, the reaction solution was extracted three times by using 30 mL of water and 30 mL of ethylacetate. Residues obtained by drying organic layers by using magnesium sulfate and evaporating a solvent were isolated and purified by using the silica gel column chromatography to obtain 5.41 g of Intermediate 2d (yield rate 80%). The Intermediate 2d produced was observed through ¹H NMR and MS/FAB. C₃₇H₂₅Br: calc. 548.11. found 548.10.

¹H NMR (CDCl₃, 400 MHz) 8.27 (d, 1H), 8.25 (d, 1H), 8.15-8.13 (m, 2H), 8.00-7.87 (m, 5H), 7.76 (d, 1H), 7.71 (d, 1H), 7.67 (d, 1H), 7.65-7.59 (m, 3H), 7.53-7.49 (m, 2H), 7.27-7.22 (m, 1H), 7.15 (d, 1H), 1.90 (s, 6H)

### Synthesis of Compound 78

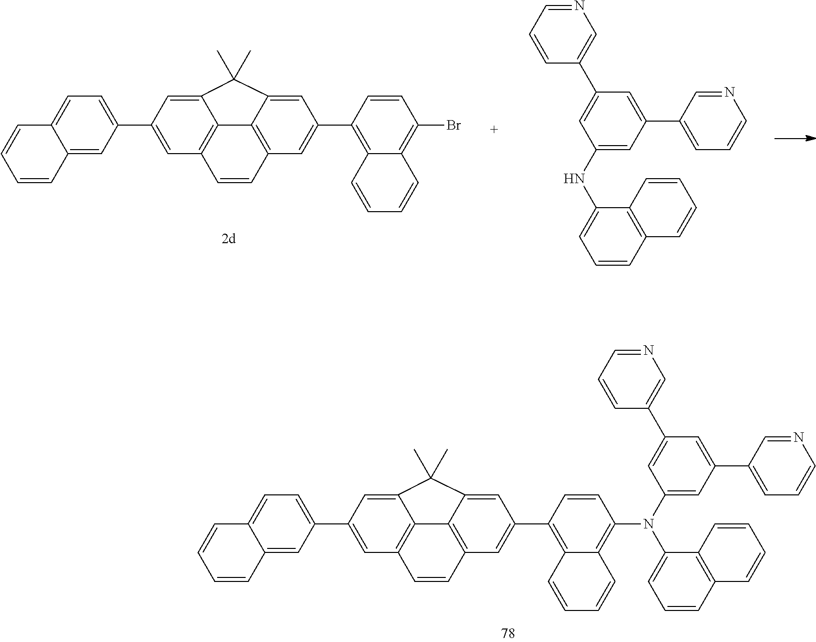 [SMILES: CC1(C)c2cc(-c3ccc4ccccc4c3)cc3ccc4cc(-c5ccc(Br)c6ccccc56)cc1c4c23 ; c1cncc(-c2cc(Nc3cccc4ccccc34)cc(-c3cccnc3)c2)c1 ; CC1(C)c2cc(-c3ccc4ccccc4c3)cc3ccc4cc(-c5ccc(N(c6cc(-c7cccnc7)cc(-c7cccnc7)c6)c6cccc7ccccc67)c6ccccc56)cc1c4c23]

5.20 g (12.3 mmol) of Intermediate 2d, 3.53 g (9.46 mmol) of (3,5-dipyridine-3-ylphenyl)-naphthalene-1-ylamine, 0.92 g (0.19 mmol) of Pd₂(dba)₃, 0.08 g (0.38 mmol) P(tBu)₃, and 1.36 g (14.2 mmol) of NaOtBu were dissolved in 70 mL of toluene and then agitated for 4 hours at a temperature of 80° C. to produce a reaction solution. After cooling the reaction solution to room temperature, 40 mL of water was added to the reaction solution, and then extracted three times by using 50 mL of ethylether. Residues obtained by drying organic layers by using magnesium sulfate and evaporating a solvent were isolated and purified by using the silica gel column chromatography to obtain 5.97 g of Compound 78 (yield rate 75%). The compound was observed through ¹H NMR and MS/FAB. C₆₃H₄₃N₃: calc. 841.35. found 841.37.

### Synthesis of Compound 90

5.26 g of Compound 90 (yield rate 70%) was synthesized in the same manner as in the Synthesis of Compound 78, except that 3-pyridine boronic acid was used instead of 4,4,5,5-tetramethyl-2-naphthalene-2-yl-[1,3,2]dioxaborolane in the synthesis of the Intermediate 2c, phenylboronic acid was used instead of 2-(4-bromo-naphthalene-1-yl)-4,4,5,5-tetramethyl-[1,3,2]dioxaborolane in the synthesis of the Intermediate 2d, and (4,6-dinaphthalene-2-yl-[1,3,5]triazine-2-yl)pyridine-3-ylamine was used instead of (3,5-dipyridine-3-ylphenyl)-naphthalene-1-ylamine in the synthesis of Compound 78. The Compound 90 was observed through ¹H NMR and MS/FAB. ¹H NMR and MS/FAB.

Additional Compounds were synthesized by using the same synthetic pathway, the same synthetic method, and by using suitable Intermediates. ¹H NMR and MS/FAB values of the Compounds are shown in Table 1.

Synthetic methods of Compounds other than the Compounds shown in Table 1 may be inferred by a person of ordinary skill in the art based on the above synthetic pathways and materials.

### Example 1

An ITO glass substrate (50×50 mm, 15 Ω/cm² 1200 Å, available from SAMSUNG-Corning) for OLED was ultrasonically washed using distilled water and then isopropanol, followed by UV ozone cleaning for about 30 minutes. The washed glass substrate with transparent electrode lines attached was loaded onto a substrate holder.

A hole transport layer was formed by vacuum depositing 4,4′,4″-Tris(N-(2-naphthyl)-N-phenyl-amino)-triphenylamine (hereinafter, 2-TNATA), a known material for a hole injection layer to form a thickness of 600 Å and by vacuum depositing 4,4′-bis[N-(1-naphthyl)-N-phenylamino]biphenyl (hereinafter, NPB), a known material for a hole transport compound into a thickness of 300 Å.

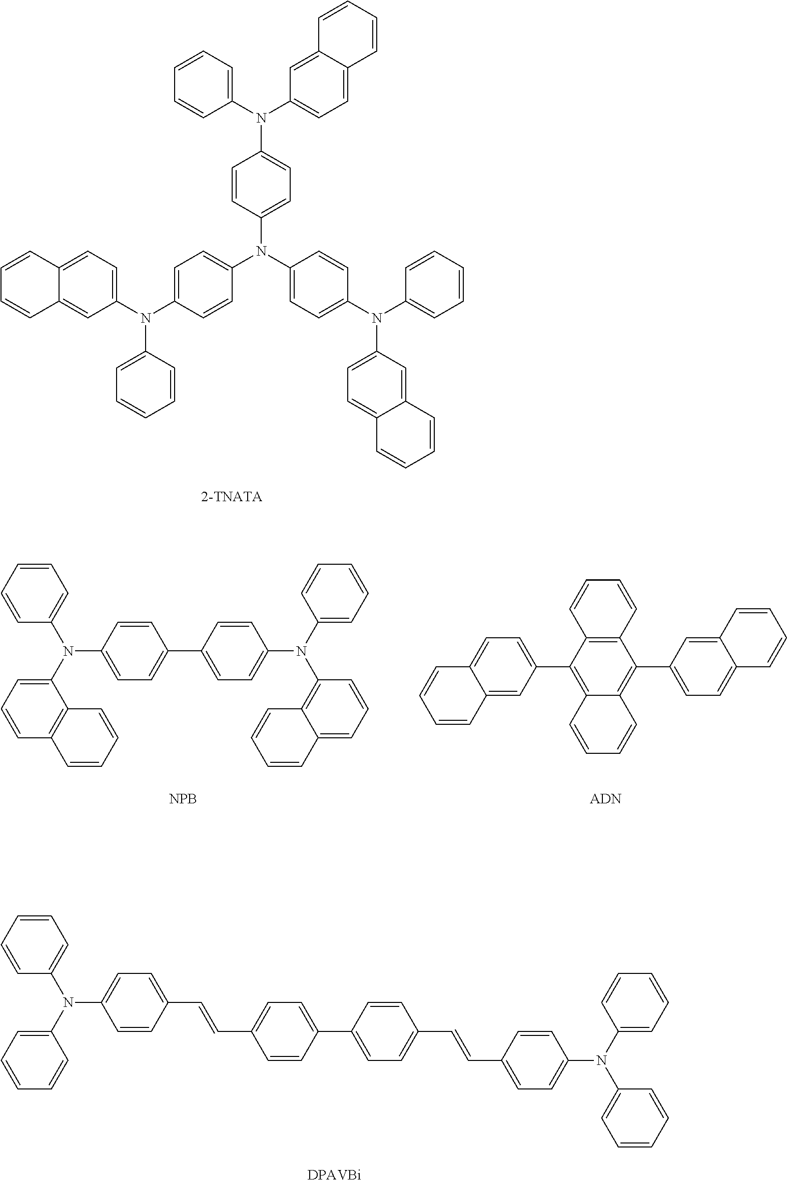

An emission layer having a thickness of 300 Å was formed by simultaneously depositing 9,10-di-naphthalene-2-yl-anthracene (hereinafter, ADN) as a blue fluorescent host, and 4,4′-bis[2-(4-(N,N-diphenylamino)phenyl)vinyl]biphenyl (hereinafter, DPAVBi), a known compound for a blue fluorescent dopant in a weight ratio of 98:2.

Thereafter, an organic light emitting device was manufactured by vacuum depositing a Compound 39 of the present inventive concept on the emission layer into a thickness of 300 Å ETL, depositing an LiF that is a halogenated alkaline metal on the ETL into a thickness of 10 Å EIL, and vacuum depositing aluminum (Al) on the EIL into a thickness of 3000 Å (a negative electrode) to form an LiF/Al electrode.

At a current density of 50 mA/cm², the device formed above showed an operating voltage of 5.11 V, a luminescence brightness of 3.910 cd/m², a luminous efficiency of 7.62 cd/A, and a half life (hr @ 100 mA/cm²) of 632 hours.

### Example 2

An organic light emitting device was manufactured in the same manner as in Example 1, except that Compound 47 was used instead of the Compound 39 in Example 1 when forming an electron transport layer.

At a current density of 50 mA/cm², the device formed above showed an operating voltage of 5.27 V, a luminescence brightness of 3.335 cd/m², a luminous efficiency of 6.88 cd/A, and a half life (hr @ 100 mA/cm²) of 563 hours.

### Example 3

An organic light emitting device was manufactured in the same manner as in Example 1, except that Compound 51 was used instead of the Compound 39 in Example 1 when forming an electron transport layer.

At a current density of 50 mA/cm², the device formed above showed an operating voltage of 5.32 V, a luminescence brightness of 3.285 cd/m², a luminous efficiency of 7.21 cd/A, and a half life (hr @ 100 mA/cm²) of 529 hours.

### Example 4

An organic light emitting device was manufactured in the same manner as in Example 1, except that Compound 54 was used instead of the Compound 39 in Example 1 when forming an electron transport layer.

At a current density of 50 mA/cm², the device formed above showed an operating voltage of 5.16 V, a luminescence brightness of 3.820 cd/m², a luminous efficiency of 7.95 cd/A, and a half life (hr @ 100 mA/cm²) of 697 hours.

### Example 5

An organic light emitting device was manufactured in the same manner as in Example 1, except that Compound 62 was used instead of the Compound 39 in Example 1 when forming an electron transport layer.

At a current density of 50 mA/cm², the device formed above showed an operating voltage of 5.00 V, a luminescence brightness of 3.895 cd/m², a luminous efficiency of 8.16 cd/A, and a half life (hr @ 100 mA/cm²) of 668 hours.

### Example 6

An organic light emitting device was manufactured in the same manner as in Example 1, except that Compound 78 was used instead of the Compound 39 in Example 1 when forming an electron transport layer.

At a current density of 50 mA/cm², the device formed above showed an operating voltage of 5.39 V, a luminescence brightness of 3.570 cd/m², a luminous efficiency of 7.53 cd/A, and a half life (hr @ 100 mA/cm²) of 603 hours.

### Example 7

An organic light emitting device was manufactured in the same manner as in Example 1, except that Compound 90 was used instead of the Compound 39 in Example 1 when forming an electron transport layer.

At a current density of 50 mA/cm², the device formed above showed an operating voltage of 5.07 V, a luminescence brightness of 3.965 cd/m², a luminous efficiency of 7.96 cd/A, and a half life (hr @ 100 mA/cm²) of 657 hours.

### Comparative Example 1

An organic light emitting device was manufactured in the same manner as in Example 1, except that a known material, Alg₃, was used instead of the Compound 39 in Example 1 when forming an electron transport layer.

At a current density of 50 mA/cm², the device formed above showed an operating voltage of 7.25 V, a luminescence brightness of 2.250 cd/m², a luminous efficiency of 4.19 cd/A, and a half life (hr @ 100 mA/cm²) of 163 hours.

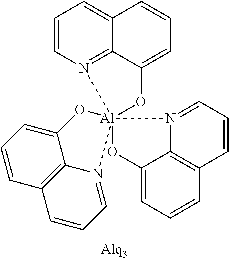

Arylamine compounds having a structure of Formula 1 according to the present inventive concept were evaluated by applying the compounds to the organic light emitting device as electron transport materials. When the compounds were used as the electron transport materials, an operating voltage of the device decreased by greater than or equal to 1 V, showed excellent I-V-L characteristic having a greatly increased efficiency, and particularly showed excellent improvement in lifespan of the device. Results and representative lifespan of the device are summarized in Table 1 below.

TABLE 1

| | Electron | Operating | Current | | | | |
|---|---|---|---|---|---|---|---|
| | transport | voltage | density | Brightness | Efficiency | Emitted | Half life |
| | material | (V) | (mA/cm²) | (cd/m²) | (cd/A) | color | (hr@100 mA/cm²) |
| Example 1 | Compound 39 | 5.11 | 50 | 3.910 | 7.62 | blue | 632 hr |
| Example 2 | Compound 47 | 5.27 | 50 | 3.335 | 6.88 | blue | 563 hr |
| Example 3 | Compound 51 | 5.32 | 50 | 3.285 | 7.21 | blue | 529 hr |
| Example 4 | Compound 54 | 5.16 | 50 | 3.820 | 7.95 | blue | 697 hr |
| Example 5 | Compound 62 | 5.00 | 50 | 3.895 | 8.16 | blue | 668 hr |
| Example 6 | Compound 78 | 5.39 | 50 | 3.570 | 7.53 | blue | 603 hr |
| Example 7 | Compound 90 | 5.07 | 50 | 3.965 | 7.96 | blue | 657 hr |
| Comparative | Alq₃ | 7.25 | 50 | 2.250 | 4.19 | blue | 163 hr |
| Example 1 | | | | | | | |

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A compound having an electron injection capability and/or electron transport capability, the compound represented by Formula 1 below: 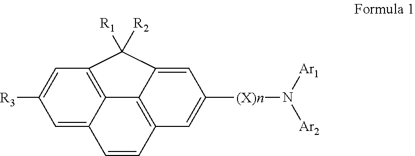
wherein R₁ and R₂ are each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group;
R₃ is hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group;
X is a connector that is a substituted or unsubstituted C₆-C₁₀ arylene group except an anthracene, a substituted or unsubstituted C₂-C₁₁ heteroarylene group, or a substituted or unsubstituted C₆-C₆₀ condensed polycyclic group;
Ar₁ and Ar₂ are each independently a substituted or unsubstituted C₂-C₆₀ heteroaryl group, a C₆-C₆₀ aryl group substituted with an electron withdrawing group, or a C₆-C₆₀ condensed polycyclic group substituted with an electron withdrawing group; and
n is an integer of 1 to 10.

2. The compound having an electron injection capability and/or electron transport capability of claim 1, wherein the electron withdrawing group is —F, —Cl, —Br, —I, —CN, a hydroxyl group, —NO₂, an amino group, an amidino group, hydrazine, hydrazone, a carboxyl group or a salt thereof, a sulfonic acid or a salt thereof, a phosphoric acid or a salt thereof, a C₂-C₆₀ heteroaryl group, a C₁-C₆₀ alkyl group substituted with at least one —F, a C₁-C₆₀ alkoxy group substituted with at least one —F, a C₂-C₆₀ alkenyl group substituted with at least one —F, or a C₂-C₆₀ alkynyl group substituted with at least one —F.

3. The compound having an electron injection capability and/or electron transport capability of claim 1, wherein R₁ and R₂ are each independently a C₁-C₃₀ alkyl group.

4. The compound having an electron injection capability and/or electron transport capability of claim 1, wherein R₃ is at least one of hydrogen, deuterium, or any one of Formulae 2a to 2d: 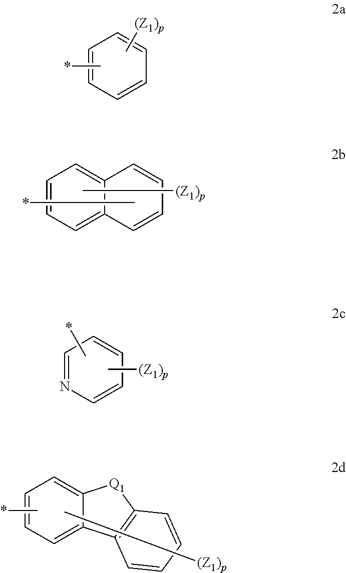
wherein in Formulae 2a to 2d, Q₁ is a connector represented by —S— or —O—;
Z₁ is hydrogen, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, or an amino group substituted with a C₆-C₂₀ aryl group or a C₂-C₂₀ heteroaryl group, a halogen group, a cyano group, a nitro group, a hydroxyl group, or a carboxy group;
p is an integer of 1 to 7; and
* represents a bonding.

5. The compound having an electron injection capability and/or electron transport capability of claim 1, wherein X is any connector of Formulae 3a to 3d: 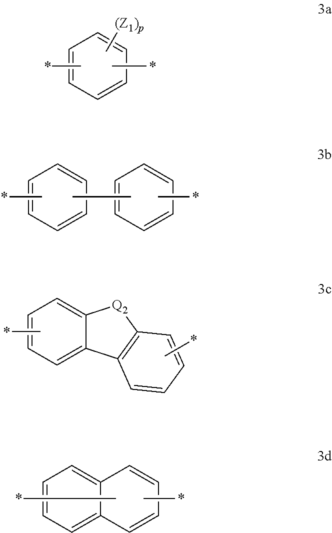
wherein in Formulae 3a to 3d Q₂ is a connector represented by —C(R₃₀)(R₃₁)—, —S— or —O—;
Z₁, R₃₀ and R₃₁ are each independently hydrogen, deuterium, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted C₆-C₂₀ condensed polycyclic group, a halogen group, a cyano group, a nitro group, a hydroxyl group, or a carboxy group;
p is an integer of 1 to 4; and
* represents a bonding.

6. The compound having an electron injection capability and/or electron transport capability of claim 1, wherein Ar₁ and Ar₂ are any one of Formulae 4a to 4e: 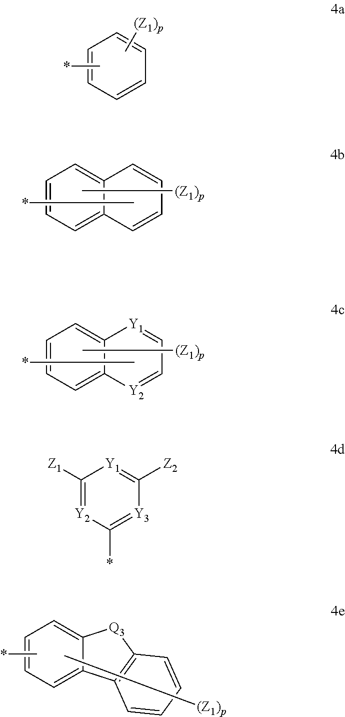
wherein in Formulae 4a to 4e Q₃ is a connector represented by —C(R₃₀)(R₃₁)—;
Z₁, Z₂, R₃₀ and R₃₁ are each independently hydrogen, deuterium, —F, —Cl, —Br, —I, —CN, a hydroxyl group, —NO₂, an amino group, an amidino group, hydrazine, hydrazone, a carboxyl group or a salt thereof, a sulfonic acid or a salt thereof, a phosphoric acid or a salt thereof, a C₂-C₆₀ heteroaryl group, a C₁-C₆₀ alkyl group substituted with at least one —F, a C₁-C₆₀ alkoxy group substituted with at least one —F, a C₂-C₆₀ alkenyl group substituted with at least one —F, a C₂-C₆₀ alkynyl group substituted with at least one —F, or a C₆-C₆₀ aryl group;
Y₁, Y₂ and Y₃ may be each independently —N═ or —CH═;
p is an integer of 1 to 7; and
* represents a bonding.

7. The compound having an electron injection capability and/or electron transport capability of claim 1, wherein the compound represented by Formula 1 is any one of compounds below:

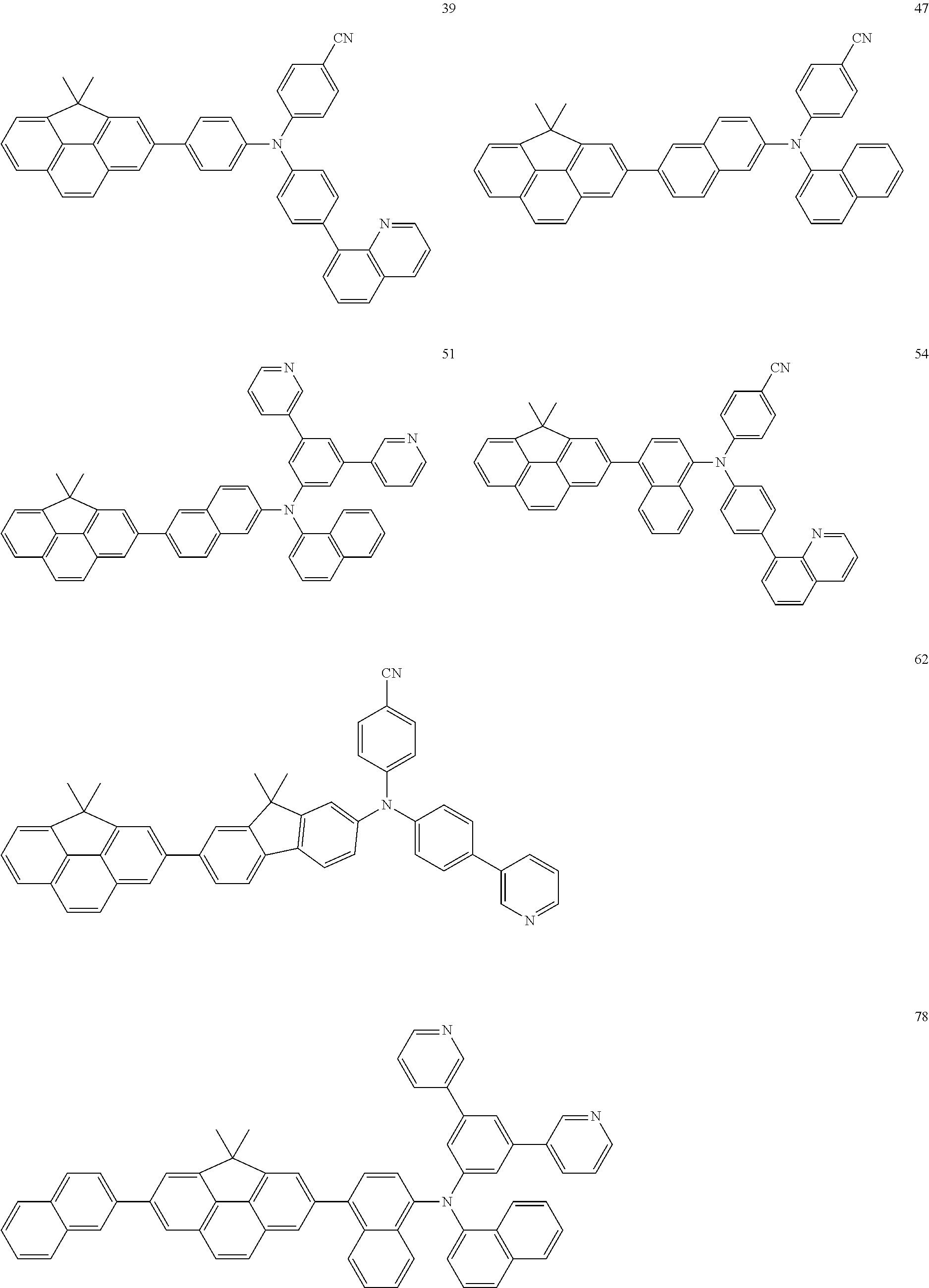

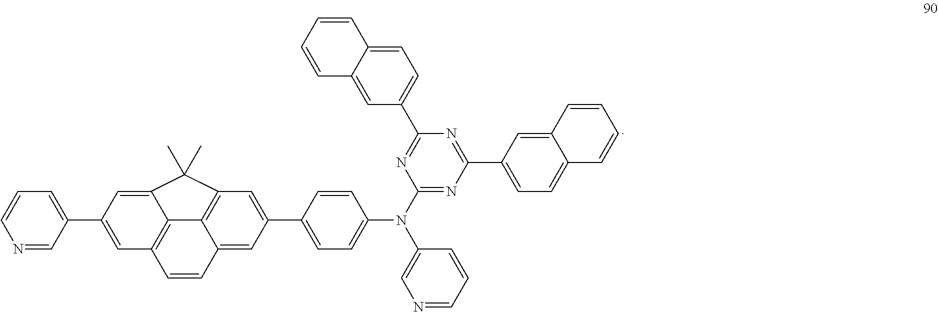 [SMILES: CC1(C)c2cc(-c3ccc(N(c4cccnc4)c4nc(-c5ccc6ccccc6c5)nc(-c5ccc6ccccc6c5)n4)cc3)cc3ccc4cc(-c5cccnc5)cc1c4c23]

8. An organic light emitting device comprising:
a first electrode;
a second electrode disposed opposite to the first electrode; and
an organic layer disposed between the first electrode and the second electrode and comprising an emission layer, wherein
the organic layer includes at least one of the compounds of claim 1.

9. The organic light emitting device of claim 8, wherein the organic layer comprises an electron injection layer, an electron transport layer, or a functional layer having both electron injection and electron transport capabilities.

10. The organic light emitting device of claim 8, wherein the organic layer comprises an emission layer, an electron injection layer, an electron transport layer, a functional layer having both electron injection and electron transport capabilities, a hole injection layer, a hole transport layer, or a function layer having both hole injection and hole transport capabilities,
wherein the electron injection layer or the functional layer having both hole injection and hole transport capabilities comprises the compound represented by Formula 1 below: 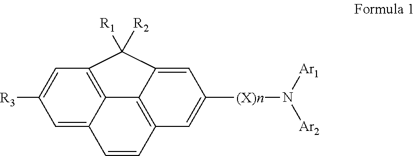
wherein R₁ and R₂ are each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group;
R₃ is hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group;
X is a connector that is a substituted or unsubstituted C₆-C₁₀ arylene group except an anthracene, a substituted or unsubstituted C₂-C₁₁ heteroarylene group, or a substituted or unsubstituted C₆-C₆₀ condensed polycyclic group;
Ar₁ and Ar₂ are each independently a substituted or unsubstituted C₂-C₆₀ heteroaryl group, a C₆-C₆₀ aryl group substituted with an electron withdrawing group, or a C₆-C₆₀ condensed polycyclic group substituted with an electron withdrawing group; and
n is an integer of 1 to 10; and
the emission layer comprises an anthracene-based compound, an arylamine-based compound, or a styryl-based compound.

11. The organic light emitting device of claim 8, wherein the organic layer comprises an emission layer, an electron injection layer, an electron transport layer, a functional layer having both electron injection and electron transport capabilities, a hole injection layer, a hole transport layer, or a functional layer having both hole injection and hole transport capabilities,
wherein the electron injection layer, the electron transport layer, or the function layer having both hole injection and hole transport capabilities comprises the compound represented by Formula 1 below: 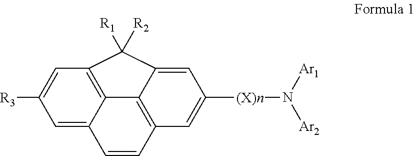
wherein R₁ and R₂ are each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group;
R₃ is hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group;
X is a connector that is a substituted or unsubstituted C₆-C₁₀ arylene group except an anthracene, a substituted or unsubstituted C₂-C₁₁ heteroarylene group, or a substituted or unsubstituted C₆-C₆₀ condensed polycyclic group;
Ar₁ and Ar₂ are each independently a substituted or unsubstituted C₂-C₆₀ heteroaryl group, a C₆-C₆₀ aryl group substituted with an electron withdrawing group, or a C₆-C₆₀ condensed polycyclic group substituted with an electron withdrawing group; and
n is an integer of 1 to 10; and
at least one layer of a red layer, a green layer, a blue layer, or a white layer of the emission layer comprises a phosphorescent compound.

12. The organic light emitting device of claim 11, wherein the electron injection layer, the electron transport layer, or the functional layer having both electron injection and electron transport capabilities comprises a charge generating material.

13. The organic light emitting device of claim 12, wherein the charge generating material is a p-type dopant.

14. The organic light emitting device of claim 13, wherein the p-type dopant is a quinone-derivative.

15. The organic light emitting device of claim 13, wherein the p-type dopant is a metal oxide.

16. The organic light emitting device of claim 13, wherein the p-type dopant is a cyano group-containing compound.

17. The organic light emitting device of claim 8, wherein the organic layer comprises an electron transport layer, and the electron transport layer comprises a metal complex.

18. The organic light emitting device of claim 17, wherein the metal complex is a lithium complex.

19. The organic light emitting device of claim 8, wherein the organic layer is formed by a wet process using the compound represented by Formula 1 below: 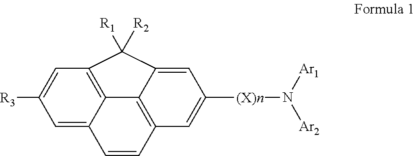
wherein R₁ and R₂ are each independently hydrogen, deuterium, a substituted or unsubstituted C₅-C₆₀ alkyl group, a substituted or unsubstituted C₆-C₆₀ aryl group, or a substituted or unsubstituted C₆-C₆₀ condensed polycyclic group;
R₃ is hydrogen, deuterium, a substituted or unsubstituted C₆-C₆₀ aryl group, a substituted or unsubstituted C₂-C₆₀ heteroaryl group, or a substituted or unsubstituted C₆-C₆₀ condensed polycyclic group;
X is a connector that is a substituted or unsubstituted C₆-C₁₀ arylene group except an anthracene, a substituted or unsubstituted C₂-C₁₁ heteroarylene group, or a substituted or unsubstituted C₆-C₆₀ condensed polycyclic group;
Ar₁ and Ar₂ are each independently a substituted or unsubstituted C₂-C₆₀ heteroaryl group, a C₆-C₆₀ aryl group substituted with an electron withdrawing group, or a C₆-C₆₀ condensed polycyclic group substituted with an electron withdrawing group; and
n is an integer of 1 to 10.

20. A flat display device comprising the organic light emitting device of claim 8, wherein the first electrode of the organic light emitting device is electrically connected to a source electrode or a drain electrode of a thin film transistor.
